(19) United States
(12) Patent Application Publication
(10) Pub. No.: US 2015/0204920 A1
(43) Pub. Date: Jul. 23, 2015

(54) ELECTRIC-QUANTITY MEASURING APPARATUS AND ELECTRIC-QUANTITY MEASURING METHOD

(71) Applicant: Kempei Seki, Chiyoda-ku (JP)

(72) Inventor: Kempei Seki, Chiyoda-ku (JP)

(73) Assignee: Mitsubishi Electric Corporation, Tokyo (JP)

(21) Appl. No.: 14/411,063

(22) PCT Filed: Aug. 17, 2012
(86) PCT No.: PCT/JP2012/070937

§ 371 Date: Dec. 23, 2014

(51) Int. Cl. G01R 19/25; G01R 19/00; G01R 23/06; G01R 19/252

(52) U.S. Cl. CPC G01R 19/2513; G01R 19/252; G01R 19/0007; G01R 23/06

(57) ABSTRACT

A frequency-coefficient calculating unit calculates, as a frequency coefficient (f_{c}), a value ((v₂₁+v₂₃)/(2v₂₂)) obtained by normalizing, with a differential voltage instantaneous value (v₂₂) at intermediate time, an average ((v₂₁+v₂₃)/2) of a sum (v₂₁+v₂₃) of differential voltage instantaneous values at time other than the intermediate time among differential voltage instantaneous value data (v₂₁, v₂₂, and v₂₃) at three points representing an inter-distal end distance between voltage instantaneous value data at adjacent two points in voltage instantaneous value data at continuous at least four points extracted, out of voltage instantaneous value data obtained by sampling a measurement target alternating-current voltage at a predetermined data collection sampling frequency, at a gauge sampling frequency lower than the data collection sampling frequency and equal to or higher than a frequency of the alternating-current voltage.

### FIELD

The present invention relates to an electric-quantity measuring apparatus and an electric-quantity measuring method.

### BACKGROUND

In recent years, as a load flow in a power system becomes more complicated, supply of electric power with higher reliability and higher quality is demanded. In particular, necessity of performance improvement of an alternating-current electric quantity measuring apparatus that measures an electric quantity (an alternating-current electric quantity) of the power system is higher than ever before.

As the alternating-current electric quantity measuring apparatus of this type, for example, there have been systems disclosed in Patent Literatures 1 and 2. Patent Literature 1 (a wide-area protection control measuring system) and Patent Literature 2 (a protection control measuring system) disclose a method of calculating the frequency of a real system using a change component (a differential component) of a phase angle as a change from a nominal frequency (50 hertz or 60 hertz).

These literatures disclose the following formulas as calculation formulas for calculating the frequency of the real system. These calculation formulas are also calculation formulas disclosed by Non Patent Literature 1.

2πΔf=dφ/dt

f(Hz)=60+Δf

Note that Patent Literature 3 is a prior patent invention by the inventor of the present application. Contents of the invention are explained below as appropriate.

### CITATION LIST

### Patent Literature

Patent Literature 1: Japanese Patent Application Laid-Open No. 2009-65766
Patent Literature 2: Japanese Patent Application Laid-Open No. 2009-71637
Patent Literature 3: Japanese Patent No. 4874438 Non Patent Literature

Non Patent Literature 1: “IEEE Standard for Power Synchrophasors for Power Systems” page 30, IEEE Std C37. 118-2005.

### SUMMARY

### Technical Problem

As explained above, the method disclosed in Patent Literatures 1 and 2 and Non Patent Literature 1 is a method of calculating a change component of a phase angle using a differential calculation. However, a change in a frequency instantaneous value of the real system is frequent and complicated and the differential calculation is extremely unstable. Therefore, for example, there is a problem in that sufficient calculation accuracy cannot be obtained concerning frequency measurement.

In these methods, the change in the phase angle is calculated using the nominal frequency (50 hertz or 60 hertz) as an initial value. Therefore, at the start of the calculation, when a measurement target is operating at an off-nominal system frequency, a measurement error occurs. When a degree of deviation from the system nominal frequency is large, there is a problem in that the measurement error is extremely large.

On the other hand, the inventor of the present application has found symmetry of an alternating-current voltage/an alternating current and proposed introduction of a group theory of a symmetric theory into an alternating-current system. The proposal was registered as a patent In Japan (Patent Literature 3). Note that Patent Literature 3 discloses a method of measuring an alternating-current electric quantity. However, there is a demand for measuring not only the alternating-current electric quantity but also a direct-current electric quantity superimposed on the alternating-current electric quantity.

The present invention has been devised in view of the above and it is an object of the present invention to provide an electric-quantity measuring apparatus and an electric-quantity measuring method that enable highly accurate measurement of electric quantities (an alternating-current electric quantity and a direct-current electric quantity) even when a measurement target is operating at a frequency deviating from an off-nominal system frequency.

### Solution to Problem

In order to solve the aforementioned problems, an electric-quantity measuring apparatus according to one aspect of the present invention is configured to include: a rotation-phase-angle calculating unit that calculates, as a rotation phase angle between adjacent voltage instantaneous value data, an arc cosine value of a value obtained by normalizing, with a differential voltage instantaneous value at intermediate time, an average of a sum of differential voltage instantaneous values at time other than the intermediate time among differential voltage instantaneous value data at three points representing an inter-distal end distance between voltage instantaneous value data at adjacent two points in voltage instantaneous value data at continuous at least four points extracted, out of voltage instantaneous value data obtained by sampling a measurement target alternating-current voltage at a predetermined first sampling frequency, at a second sampling frequency lower than the first sampling frequency and equal to or higher than a frequency of the alternating-current voltage; and a frequency calculating unit that calculates a frequency of the alternating-current voltage using the second sampling frequency and the rotation phase angle.

### Advantageous Effects of Invention

According to the present invention, there is an effect that highly accurate measurement of an electric quantity is possible even when the measurement target is operating at an off-nominal system frequency.

### BRIEF DESCRIPTION OF DRAWINGS

FIG. 1 is a diagram for explaining symmetry between a rotation phase angle and a real-time frequency.

FIG. 2 is a diagram of a gauge voltage group on a complex plane in which a positive number rotation phase angle is used.

FIG. 3 is a diagram of a gauge voltage group on a complex plane in which a negative number rotation phase angle is used.

FIG. 4 is a diagram of a vector product element of the gauge voltage group shown on a complex plane.

FIG. 5 is a diagram for explaining a relation between a gauge sampling cycle T and a data collection sampling cycle T₁.

FIG. 6 is a diagram of a rotation voltage group on a complex plane.

FIG. 7 is a diagram of a vector product element of the rotation voltage group shown on a complex plane.

FIG. 8 is a diagram of a gauge differential voltage group on a complex plane in which a positive number rotation phase angle is used.

FIG. 9 is a diagram of a gauge differential voltage group on a complex plane in which a negative number rotation phase angle is used.

FIG. 10 is a diagram of a vector product element of the gauge differential voltage group shown on a complex plane.

FIG. 11 is a diagram of a characteristic triangle by a gauge voltage and a gauge differential voltage.

FIG. 12 is a diagram of a rotation differential voltage group on a complex plane.

FIG. 13 is a diagram of a vector product element of the rotation differential voltage group shown on a complex plane.

FIG. 14 is a diagram of a gauge voltage group on a complex plane including a direct-current component.

FIG. 15 is a frequency characteristic chart of a frequency coefficient at a gauge sampling frequency of 200 hertz.

FIG. 16 is a frequency characteristic chart of a rotation phase angle at the gauge sampling frequency of 200 hertz.

FIG. 17 is a frequency gauge characteristic chart of a voltage amplitude measurement value at the gauge sampling frequency of 200 hertz.

FIG. 18 is a frequency gain characteristic chart of a frequency measurement value at the gauge sampling frequency of 200 hertz.

FIG. 19 is a diagram of a functional configuration of a real-time frequency measuring apparatus according to a first embodiment.

FIG. 20 is a flowchart for explaining a flow of processing in the real-time frequency measuring apparatus according to the first embodiment.

FIG. 21 is a diagram of a voltage instantaneous value waveform in a case 1.

FIG. 22 is a diagram of a measurement result of a frequency coefficient in the case 1.

FIG. 23 is a diagram of a measurement result of a rotation phase angle in the case 1.

FIG. 24 is a diagram of a measurement result of a real-time frequency in the case 1.

FIG. 25 is a diagram of a voltage instantaneous value waveform in a case 2.

FIG. 26 is a diagram of a measurement result of a frequency coefficient in the case 2.

FIG. 27 is a diagram of a measurement result of a rotation phase angle in the case 2.

FIG. 28 is a diagram of a measurement result of a real-time frequency in the case 2.

FIG. 29 is a diagram of a first voltage instantaneous value waveform in a case 3.

FIG. 30 is a diagram of a second voltage instantaneous value waveform in the case 3.

FIG. 31 is a diagram of a measurement result of a frequency coefficient in the case 3.

FIG. 32 is a diagram of a measurement result of a rotation phase angle in the case 3.

FIG. 33 is a diagram of a measurement result of a real-time frequency in the case 3.

FIG. 34 is a diagram of a functional configuration of a voltage measuring apparatus according to a second embodiment.

FIG. 35 is a flowchart for explaining a flow of processing in the voltage measuring apparatus according to the second embodiment.

FIG. 36 is a diagram of a voltage instantaneous value waveform and a measurement result of an alternating-current voltage amplitude superimposed with a direct-current voltage in a case 4.

FIG. 37 is a diagram of a measurement result of an alternating-current voltage amplitude in the case 4.

FIG. 38 is a diagram of a measurement result of a direct-current voltage in the case 4.

FIG. 39 is a diagram of a voltage instantaneous value waveform and a measurement result of an alternating-current voltage amplitude superimposed with a direct-current voltage in a case 5.

FIG. 40 is a diagram of a measurement result of an alternating-current voltage amplitude in the case 5.

FIG. 41 is a diagram of a measurement result of a direct-current voltage in the case 5.

### DESCRIPTION OF EMBODIMENTS

Electric-quantity measuring apparatuses and electric-quantity measuring methods according to embodiments of the present invention are explained below with reference to the accompanying drawings. Note that the present invention is not limited by the embodiments explained below.

(Meanings of Terms)

First, in explaining the electric-quantity measuring apparatuses and the electric-quantity measuring methods according to the embodiments, terms used in this specification are explained.

Complex number: A number represented in a form of a+jb using real numbers a and b and an imaginary number unit j. In the electric engineering, because i is a current sign, the imaginary number unit is represented by j=√(−1). In this application, a rotation vector is represented using the complex number.

Complex plane: A plane representing a complex number with rectangular coordinates in which a complex number is set as a point on a two-dimensional plane, a real part (Re) is plotted on the abscissa, and an imaginary part (Im) is plotted on the ordinate.

Rotation vector: A vector that rotates counterclockwise on a complex plane concerning an electric quantity (a voltage or an electric current) of a power system. A real number part of the rotation vector is an instantaneous value.

Differential rotation vector: A differential vector of rotation vectors at two points before and after one cycle of a sampling frequency. A real number part of the differential rotation vector is a difference between instantaneous values of the two points before and after one cycle of the sampling frequency.

Symmetric group: A group having symmetry that rotates on the complex plane.

Invariant: A parameter that does not change before and after the symmetric group rotates. As the invariant in this application, there are a rotation phase angle, a frequency coefficient, a gauge voltage, a gauge differential voltage, and the like. Note that, if the invariant is known, a characteristic of the symmetric group is also known.

Vector multiplication table: A table represented by a product (multiplication) of predetermined members (vector variables) in the symmetric group. The vector multiplication table is a roadmap for checking the invariant of the symmetric group.

Real number multiplication table: A table represented by a product (multiplication) of predetermined members (real number variables) in the symmetric group.

Real-time frequency: A real frequency in the power system. The real frequency slightly fluctuates in the vicinity of a nominal frequency even if the power system is stable. In this application, the real-time frequency is represented by f. A unit of the real-time frequency f is hertz (Hz). An angular frequency ω in an electric circuit or the like is represented by ω=2πf, and the unit of the angular frequency ω is (rad/s).

Data collection sampling frequency: A sampling frequency (a first sampling frequency) during data collection. The data collection sampling frequency is represented by a sign f₁. Accuracy is higher when the data collection sampling frequency f₁ is higher. Note that, like the gauge sampling cycle T, a data collection sampling cycle T₁ is represented by T₁=1/f₁ as an inverse of the data collection sampling frequency f₁.

Gauge sampling frequency: A sampling frequency (a second sampling frequency) used in calculation of a gauge symmetric group. The gauge sampling frequency is represented by a sign fₛ. Therefore, the gauge sampling cycle T is represented by T=1/fₛ as an inverse of the gauge sampling frequency fₛ. Note that there is a relation of T>T₁ between T and T₁.

System frequency: Basically, the system frequency means a nominal frequency in the power system. There are two kinds, i.e., 50 hertz and 60 hertz.

Rotation phase angle: A phase angle at which a voltage rotation vector (sometimes simply referred to as “voltage vector”) or a current rotation vector (sometimes simply referred to as “current vector”) rotates on the complex plane in one cycle of the gauge sampling frequency. The rotation phase angle is represented by α. Note that the rotation phase angle α is a frequency dependent amount. As explained below, when α is a positive number, the rotation phase angle α is calculated by α=2π(f/fₛ). When α is a negative number, the rotation phase angle α is calculated by α=2π{f(f/fₛ)−1}. When α is zero, there is a relation f=fₛ/2 between the gauge sampling frequency fₛ and the real-time frequency f.

Frequency coefficient: A cosine function value of the rotation phase angle α. The frequency coefficient is represented by f_{c}. All gauge symmetric groups of this application include respective calculation formulas for frequency coefficients. Note that, if the frequency coefficient f_{c} is used as a symmetry index, it is possible to determine whether an electric current is an alternating current.

Moving average processing: Simple averaging processing performed using a predetermined number of most recent data. Note that, by performing the moving average processing, it is possible to reduce the influence of a measurement error and additive Gaussian noise.

Gauge voltage group: A symmetric group configured by three voltage vectors continuous in time series. Note that the same concept of the symmetric group can be defined concerning an electric current and electric power (active power and reactive power) other than the voltage.

Gauge voltage: A voltage invariant calculated by the gauge voltage group.

Gauge differential voltage group: A symmetric group configured by three differential voltage vectors continuous in time series.

Gauge differential voltage: A differential voltage invariant calculated by the gauge differential voltage group.

Rotation voltage group: A symmetric group configured by continuous two voltage vectors. A measured voltage instantaneous value is equivalent to a real number part of a voltage vector.

Rotation differential voltage group: A symmetric group configured by continuous two differential voltage vectors.

Break of symmetry: Collapse of an input waveform from a pure sine wave. The symmetry of the input waveform is broken by an amplitude sudden change, a phase sudden change, or a frequency sudden change. An index for determining (detecting) the break of the symmetry is a symmetry index.

(Points of the Present Invention)

The present invention is an invention concerning an electric-quantity measuring apparatus that is a basic technology of smart grid. One of points of the present invention is simultaneous treatment of a frequency domain and an instantaneous value domain through a rotation phase angle. More specifically, the point is in modeling, as a group of symmetry, an alternating-current voltage and an alternating current and a structure of direct-current components (a direct-current voltage and a direct current) included in the alternating-current voltage and the alternating current). In a conventional theory, analyses are separately performed in a frequency domain and a time domain. However, in the present invention, analyses of frequency depending amounts (a rotation phase angle, a frequency coefficient, a real-time frequency, and an amplitude) and a time dependent amount (a voltage current instantaneous value) are simultaneously performed using various symmetric groups (vector symmetric groups) on the complex plane defined above.

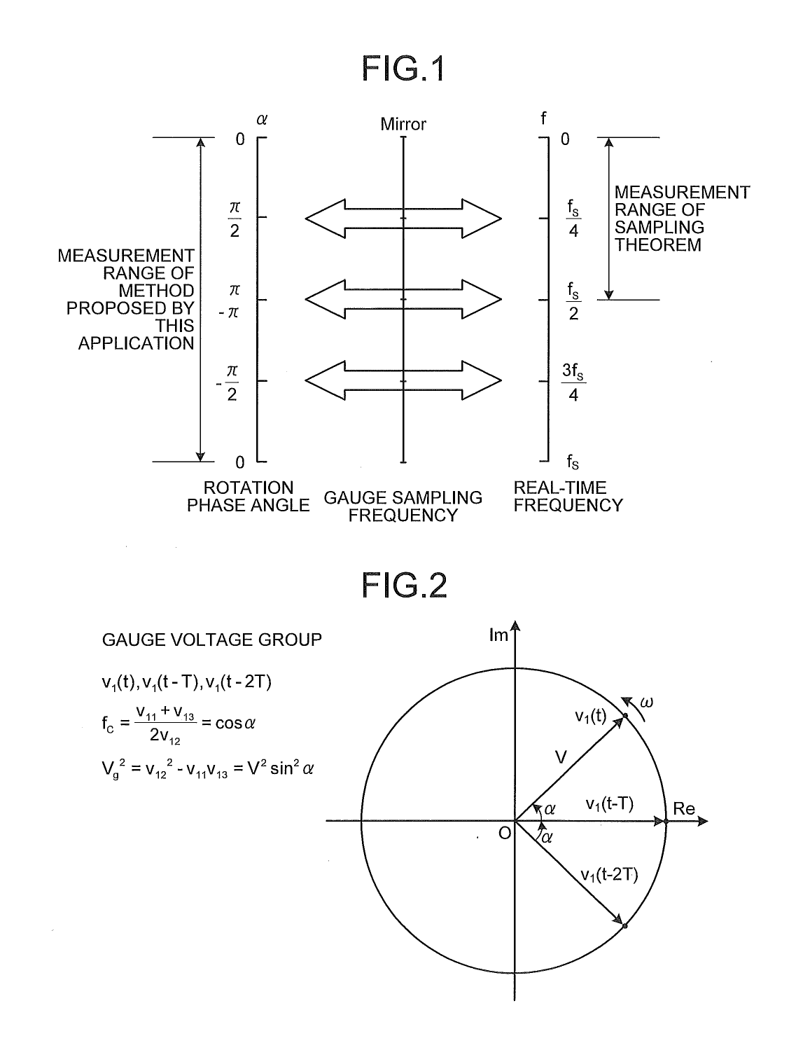

A highest-order concept of the present invention is symmetry of a rotation phase angle and a real-time frequency (see FIG. 1). According to the present invention, by introducing a rotation phase angle that takes a negative value (hereinafter referred to as “negative value rotation phase angle”), it is made possible to measure a frequency of an entire region corresponding to a gauge sampling frequency ((in the conventional method, only a frequency equal to or lower than a half of a sampling frequency (in the present invention, a gauge sampling frequency) can be decided)). That is, according to a symmetric group measurement theory of the present invention, a measurement result is expanded to a double compared with the conventional measurement range.

A second point of the present invention is to generate a vector multiplication table of symmetric groups, check structures of symmetric groups in a vector product space, generate a real number multiplication table of same symmetric groups from the structures, and derive a specific calculation formula for an invariant. The vector multiplication table is a roadmap for checking an invariant of a symmetric group. The inventor of the present application found various invariants such as a frequency coefficient and a gauge voltage in a gauge differential voltage group in the applications in the past. However, general answers have not been found concerning how many invariants of the symmetric group are present and what kinds of structures calculation formulas of the respective invariants have.

On the other hand, in the present invention, by proposing two kinds of multiplication tables, a new invariant (a invariant defined anew) equivalent to a high-order concept of the invariants in the past could be found. Note that, when the present invention is applied to a specific application, a practical invariant among listed invariants only has to be selected.

A third point of the present invention is to propose a method of separating a gauge sampling frequency and a data collection sampling frequency. If this method is used, high-speed and highly accurate measurement is possible.

Further, a fourth point of the present invention is to propose a method of measuring not only an alternating-current electric quantity but also a direct-current electric quantity. According to this characteristic, in the present invention, the conventional invention title “alternating-current electric quantity measuring apparatus (method)” is changed to “electric-quantity measuring apparatus (method)”.

An electric-quantity measuring apparatus and an electric-quantity measuring method according to an embodiment are explained. In this explanation, first, a concept (an algorithm) of an electric-quantity measuring method forming a point of this embodiment is explained. Thereafter, the configuration and the operation of the electric-quantity measuring apparatus according to this embodiment, which is an applied apparatus of this method, and an electric-quantity measuring method according to this embodiment to which this method is applied are explained. Note that, in the following explanation, among lower-case letters of alphabets, parenthesized letters (e.g., “v(t)”) represent vectors and non-parenthesized letters (e.g., “v₂”) represent instantaneous values. Upper-case letters of alphabets (e.g., V_{g}”) represent root mean square values or amplitude values.

(Symmetry of a Rotation Phase Angle and a Real-Time Frequency)

FIG. 1 is a diagram for explaining symmetry between a rotation phase angle and a real-time frequency. For example, in Patent Literature 3 and the like, a calculation method based on the following relational expression is developed.

$$\begin{matrix}[ Math . 1 ] & \\ \frac{f}{{f}_{s}} = \frac{α}{2 π} & ( 1 )\end{matrix}$$

In the above formula, f represents a real-time frequency, fₛ represents a gauge sampling frequency, and α represents a rotation phase angle. The rotation phase angle α is a positive number of zero to π. A measurement range of the phase rotation angle α is equal to or smaller than a half of the gauge sampling frequency, which is the same as a limit of a sampling theorem. Thereafter, the inventor of the present application has found out that the following relational expression is true if a negative rotation phase angle of minus π to zero is introduced.

$$\begin{matrix}[ Math . 2 ] & \\ \frac{{f}_{s} - f}{{f}_{s}} = \frac{- α}{2 π} & ( 2 )\end{matrix}$$

For the above two formulas, as shown in FIG. 1, with the gauge sampling frequency set as a mirror, it is possible to establish a one-to-one symmetrical relation between the rotation phase angle and the real-time frequency. As a result, it is possible to double the measurement range of the sampling theorem. In this way, the method of this application expands a calculation range not only to a frequency domain but also to an instantaneous value domain via the rotation phase angle. On the other hand, the sampling theorem can be considered an algorithm for only the frequency domain based on Fourier transform.

Summarizing the above, an expression formula of the rotation phase angle using the real-time frequency is as follows:

$$\begin{matrix}[ Math . 3 ] & \\ α = \{ \begin{matrix}2 π \frac{f}{{f}_{s}} & for f < \frac{{f}_{s}}{2} , \\ 2 π ( \frac{f}{{f}_{s}} - 1 ) & for f > \frac{{f}_{s}}{2} .\end{matrix} & ( 3 )\end{matrix}$$

According to the above formula, it is seen that a positive number rotation phase angle (a first formula) and a negative number rotation phase angle (a second formula) have symmetry with respect to zero. As it is seen from this formula, symmetry is present in all formulas in this application. Symmetry is a guideline of this application.

Similarly, an expression formula of the real-time frequency using the rotation phase angle is as follows:

$$\begin{matrix}[ Math . 4 ] & \\ f = \{ \begin{matrix}\frac{α}{2 π} {f}_{s} & for α > 0 , \\ ( \frac{α}{2 π} + 1 ) {f}_{s} & for α < 0 , \\ \frac{{f}_{s}}{2} & for α = 0.\end{matrix} & ( 4 )\end{matrix}$$

As it is evident from the above two formulas, if the rotation phase angle is known, the real-time frequency is also known. Further, if the real-time frequency is known, highly accurate other electric quantity measurements having a frequency correction function can also be performed by calculation of a symmetric group.

A method of generating several symmetric groups, calculating a rotation phase angle and other invariants of the symmetric groups, and measuring various electric quantities is proposed below.

(A Gauge Voltage Group on a Complex Plane)

FIG. 2 is a diagram of a gauge voltage group on a complex plane in which a positive rotation phase angle is used. Three voltage rotation vectors on the complex plane shown in FIG. 2 can be represented by the following formula:

$$\begin{matrix}[ Math . 5 ] & \\ \{ \begin{matrix}{v}_{1} ( t ) = V {e}^{j ( ω t + α )} \\ {v}_{1} ( t - T ) = V {e}^{jω t} \\ {v}_{1} ( t - 2 T ) = V {e}^{j ( ω t - α )}\end{matrix} & ( 5 )\end{matrix}$$

In the above formula, V represents an alternating-current voltage amplitude, ω represents rotation angular velocity, T represents the gauge sampling cycle, and α represents a rotation phase angle at T. In FIG. 2, two voltage rotation vectors v₁(t) and V₁(t−2T) on both sides have symmetry with respect to a voltage rotation vector V₁(t−T) in the middle. Further, at another time, even if the three voltage rotation vectors rotate and are present in other places, the rotation phase angle α, which is a phase angle difference between any two of the voltage rotation vectors, does not change. This characteristic is referred to as rotation invariance. The three voltage rotation vectors having such a characteristic of the rotation invariance is defined as a gauge voltage group.

(Negative Number Rotation Phase Angle)

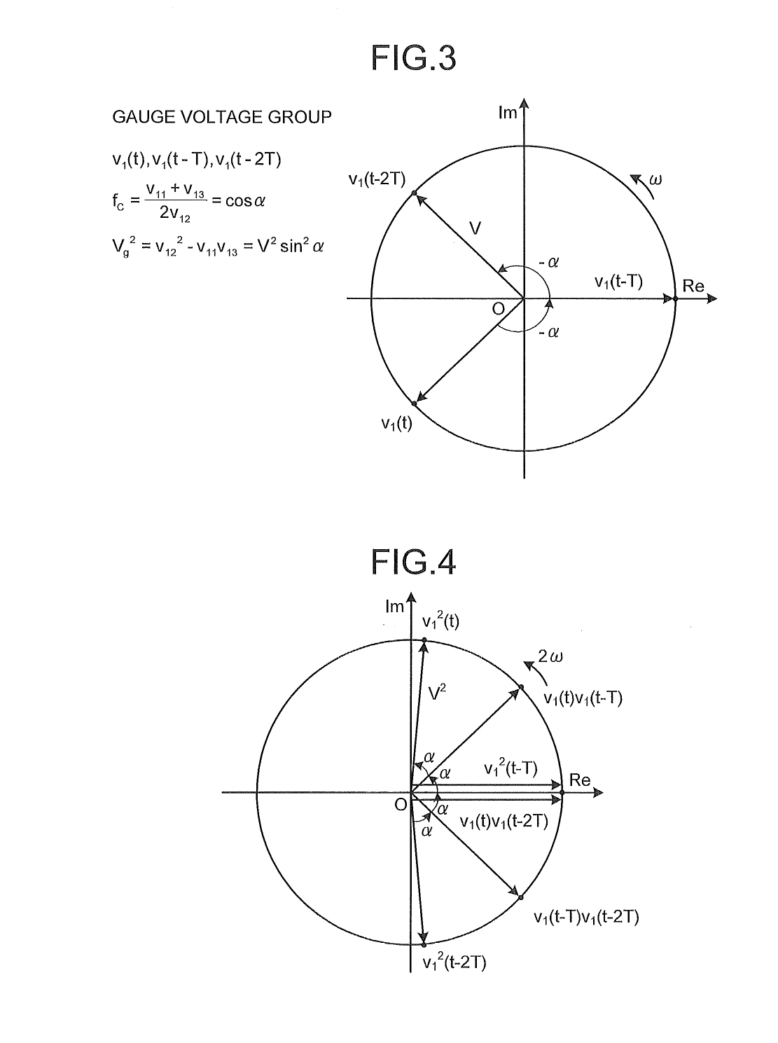

FIG. 3 is a diagram of a gauge voltage group on a complex plane in which a negative number rotation phase angle is used. When a rotation phase angle between voltage rotation vectors is larger than 180 degrees, a negative number rotation phase angle defined by the following formula is used.

[Math. 6]

α=−(360−αᵣₑₐₗ) (6)

In the above formula, αᵣₑₐₗ represents a phase angle between members of an actual gauge voltage group and is a positive number that takes a value between 180 degrees and 360 degrees. As shown in FIG. 3, in this case, as in the case explained above, the members of the gauge voltage group have symmetry (symmetry with respect to an intermediate rotation vector). That is, rotation phase angles of the gauge voltage group have rotation invariance even if the rotation phase angles are minus.

(A Vector Multiplication Table of the Gauge Voltage Group)

To check an invariant of the gauge voltage group, a vector multiplication table of the gauge voltage group shown in Table 1 below is established.

TABLE 1
A vector group table of the gauge voltage group

| x | v₁(t) | v₁(t − T) | v₁(t − 2T) |
|---|---|---|---|
| v₁(t) | v₁²(t) | v₁(t − T)v₁(t) | v₁(t − 2T)v₁(t) |
| v₁(t − T) | v₁(t)v₁(t − T) | v₁²(t − T) | v₁(t − 2T)v₁(t − T) |
| v₁(t − 2T) | v₁(t)v₁(t − 2T) | v₁(t − T)v₁(t − 2T) | v₁²(t − 2T) |

Voltage rotation vectors shown in the vector multiplication table are complex number state variables. An “×” sign in the table means that multiplication of an element on a table side and an element at a table top is performed. In this case, product elements of the vector multiplication table of the gauge voltage group can be represented as indicated by the following formula:

$$\begin{matrix}[ Math . 7 ] & \\ \{ \begin{matrix}{v}_{1}^{2} ( t ) = {V}^{2} {e}^{j ( 2 ω t + 2 α )} \\ {v}_{1} ( t ) {v}_{1} ( t - T ) = {V}^{2} {e}^{j ( 2 ω t + α )} \\ {v}_{1} ( t ) {v}_{1} ( t - 2 T ) = {V}^{2} {e}^{j ( 2 ω t )} \\ {v}_{1}^{2} ( t - T ) = {V}^{2} {e}^{j ( 2 ω t )} \\ {v}_{1} ( t - T ) {v}_{1} ( t - 2 T ) = {V}^{2} {e}^{j ( 2 ω t - α )} \\ {v}_{1}^{2} ( t - 2 T ) = {V}^{2} {e}^{j ( 2 ω t - 2 α )}\end{matrix} & ( 7 )\end{matrix}$$

A diagram in which elements based on the above formula are represented on a complex plane is FIG. 4. A space generated by product calculation of two vectors is referred to as vector product space. Symmetry intrinsic in an alternating-current sine wave can be seen using the vector product space. In the vector product space, vector product elements rotate counterclockwise at angular velocity of 2ω. Three kinds of symmetry are selected and explained below.

A first set having symmetry is a set of v₁²(t−T) and v₁(t)v₁(t−2T) located on an intermediate axis (in an example shown in FIG. 4, a real axis (Re axis)) of rotation vectors. As indicated by the following formula, results of vector products v₁²(t−T) and (t) (t−2T) are equal.

[Math. 8]

v₁²(t−T)=v₁(t)v₁(t−2T)=V²ₑ^{j(2ωt)} (8)

As it is evident from a calculation formula described below, a gauge voltage proposed before (e.g., Patent Literature 3) is formed by these sets.

A second set having symmetry is a set of v₁(t)v₁(t−T) and v₁(t−T)v₁(t−2T), and this set has a phase difference α with respect to the intermediate axis. According to a calculation formula described below, a frequency coefficient can be formed by the set.

A third set having symmetry is a set of v₁²(t) and v₁²(t−2T), and this set has a phase difference 2α with respect to the intermediate axis. According to a calculation formula described below, a gauge voltage of only a square formula can be formed by this set and a rotation vector v₁(t−T) in the middle.

If a vector product space diagram created using the vector multiplication table of the gauge voltage group is used in this way, symmetry of the gauge voltage group can be intuitively checked.

(A Real Number Multiplication Table of a Gauge Voltage Group)

To derive a calculation formula of an invariant of a gauge voltage group, a real number multiplication table of a gauge voltage group shown in Table 2 below is established. Note that, as voltage instantaneous values in the real number multiplication table, a real number part of a voltage rotation vector is used. However, an imaginary number part of the voltage rotation vector can be used.

TABLE 2
A real number group table of the gauge voltage group

| x | v₁₁ | v₁₂ | v₁₃ |
|---|---|---|---|
| v₁₁ | v²₁₁ | v₁₂v₁₁ | v₁₃v₁₁ |
| v₁₂ | v₁₁v₁₂ | v²₁₂ | v₁₃v₁₂ |
| v₁₃ | v₁₁v₁₃ | v₁₂v₁₃ | v²₁₃ |

The real number multiplication table of the gauge voltage group is explained. First, instantaneous value elements, which are constituent elements of a set in Table 2, can be represented by the following Formula:

$$\begin{matrix}[ Math . 9 ] & \\ \{ \begin{matrix}{v}_{11} = Re [ {v}_{1} ( t ) ] = V cos ( ω t + α ) \\ {v}_{12} = Re [ {v}_{1} ( t - T ) ] = V cos ( ω t ) \\ {v}_{13} = Re [ {v}_{1} ( t - 2 T ) ] = V cos ( ω t - α )\end{matrix} & ( 9 )\end{matrix}$$

In the above formula, “Re” indicates a real number part of a complex number. According to the above formula, product elements shown in Table 2 can be represented as indicated by the following formula:

$$\begin{matrix}[ Math . 10 ] & \\ \{ \begin{matrix}{v}_{11}^{2} = {V}^{2} {cos}^{2} ( ω t + α ) \\ {v}_{12} {v}_{11} = {V}^{2} cos ( ω t + α ) cos ( ω t ) \\ {v}_{13} {v}_{11} = {V}^{2} cos ( ω t + α ) cos ( ω t - α ) \\ {v}_{12}^{2} = {V}^{2} {cos}^{2} ( ω t ) \\ {v}_{13} {v}_{12} = {V}^{2} cos ( ω t ) cos ( ω t - α ) \\ {v}_{13}^{2} = {V}^{2} {cos}^{2} ( ω t - α )\end{matrix} & ( 10 )\end{matrix}$$

A calculation formula of various invariants related to the gauge voltage group is explained using the product elements of the real number multiplication table of the gauge voltage group.

(A Calculation Formula of a Frequency Coefficient by the Gauge Voltage Group)

A calculation formula of a frequency coefficient by the gauge voltage group is explained below. To derive a relation between a calculation formula of a frequency coefficient and a real number multiplication table proposed in Patent Literature 3 or the like, the inventor of the present application has performed formula transformation shown below and substituted the product elements of the real number multiplication table shown in Table 2 in the transformed formula with reference to the space vector diagram of the gauge voltage group shown in FIG. 4.

$$\begin{matrix}[ Math . 11 ] & \\ \begin{matrix}{f}_{c} = \frac{{v}_{11} + {v}_{13}}{2 {v}_{12}} \\ = \frac{{v}_{12} {v}_{11} + {v}_{13} {v}_{12}}{2 {v}_{12}^{2}} \\ = \frac{{V}^{2} [ cos ( ω t + α ) cos ( ω t ) + cos ( ω t - α ) cos ( ω t ) ]}{2 {V}^{2} {cos}^{2} ( 2 ω t )} \\ = cos α\end{matrix} & ( 11 )\end{matrix}$$

As it is evident from the formula transformation, a frequency coefficient f_{c} of the gauge voltage group can be calculated using the product elements of the real number multiplication table.

It is verified that an imaginary number part of the voltage rotation vector can be used as voltage instantaneous values. First, imaginary number part instantaneous values of v₁(t), v₁(t−T), and V₁(t−2T) can be represented by the following formula:

$$\begin{matrix}[ Math . 12 ] & \\ \{ \begin{matrix}{v}_{11} = Im [ {v}_{1} ( t ) ] = V sin ( ω t + α ) \\ {v}_{12} = Im [ {v}_{1} ( t - T ) ] = V sin ( ω t ) \\ {v}_{13} = Im [ {v}_{1} ( t - 2 T ) ] = V sin ( ω t - α )\end{matrix} & ( 12 )\end{matrix}$$

In the above formula, “Im” indicates an imaginary number part of a complex number. According to the above formula, the product elements shown in Table 2 can be represented as indicated by the following formula:

$$\begin{matrix}[ Math . 13 ] & \\ \{ \begin{matrix}{v}_{11}^{2} = {V}^{2} {sin}^{2} ( ω t + α ) \\ {v}_{12} {v}_{11} = {V}^{2} sin ( ω t + α ) sin ( ω t ) \\ {v}_{13} {v}_{11} = {V}^{2} sin ( ω t + α ) sin ( ω t - α ) \\ {v}_{12}^{2} = {V}^{2} {sin}^{2} ( ω t ) \\ {v}_{13} {v}_{12} = {V}^{2} sin ( ω t ) sin ( ω t - α ) \\ {v}_{13}^{2} = {V}^{2} {sin}^{2} ( ω t - α )\end{matrix} & ( 13 )\end{matrix}$$

Therefore, if the product elements are substituted in Formula (11), Formula (11) can be transformed as indicated by the following formula:

$$\begin{matrix}[ Math . 14 ] & \\ \begin{matrix}{f}_{c} = \frac{{v}_{11} + {v}_{13}}{2 {v}_{12}} \\ = \frac{{v}_{12} {v}_{11} + {v}_{13} {v}_{12}}{2 {v}_{12}^{2}} \\ = \frac{{V}^{2} [ sin ( ω t + α ) sin ( ω t ) + sin ( ω t - α ) sin ( ω t ) ]}{2 {V}^{2} {sin}^{2} ( 2 ω t )} \\ = cos α\end{matrix} & ( 14 )\end{matrix}$$

As it is evident from Formulas (11) and (14), the same frequency coefficient is obtained irrespective of whether a real number part is used or an imaginary number part is as a voltage instantaneous value. Note that the same applies to invariants other than the gauge voltage group and invariants of other symmetric groups in the present invention. The same calculation result is derived irrespective of whether a real number part of a rotation vector is used or an imaginary number part of the rotation vector is used. Therefore, in the following explanation, only a case in which a real number instantaneous value is used for calculation is explained, and explanation of calculation performed using an imaginary number instantaneous value is omitted.

(A Symmetry Index of the Gauge Voltage Group)

The following formula is proposed as a symmetry index of the gauge voltage group.

$$\begin{matrix}[ Math . 15 ] & \\ \vert {f}_{c} \vert = \vert \frac{{v}_{11} + {v}_{13}}{2 {v}_{12}} \vert > 1 & ( 15 )\end{matrix}$$

When the above formula is satisfied, the symmetry of the gauge voltage group established by v₁(t), v₁(t−T), and v₁(t−2T) is broken. Therefore, at a point in time when the symmetry of the gauge voltage group is broken, a calculation value before the break of the symmetry is latched. On the other hand, when the above formula is not satisfied, it is determined that the symmetry is not broken, and the present calculation value is used. Note that it is also possible to omit these steps and perform calculation using the gauge differential voltage group. However, a calculation obtained by using the gauge voltage group is obtained earlier than a calculation result obtained by using the gauge differential voltage group by one step of symmetric group pitch width (when the gauge sampling frequency is 240 hertz, the one step time pitch width is 4.167 milliseconds). That is, it is seen that, when there is symmetry, the calculation has higher speed when the gauge voltage group is used.

(A Rotation Phase Angle by the Gauge Voltage Group)

From the above calculation formula, a rotation phase angle can be calculated using the following formula:

$$\begin{matrix}[ Math . 16 ] & \\ α = \{ \begin{matrix}{cos}^{- 1} {f}_{c} & for f \leq {f}_{s} / 2 , \\ - {cos}^{- 1} {f}_{c} & for {f}_{s} / 2 \leq f < {f}_{s} .\end{matrix} & ( 16 )\end{matrix}$$

(A Moving Average of the Rotation Phase Angle)

When the rotation phase angle is calculated, to reduce the influence of noise, it is effective to perform moving average processing indicated by, for example, the following formula:

$$\begin{matrix}[ Math . 17 ] & \\ α = \frac{1}{M} {\sum }_{k = 0}^{M - 1} α ( t - {kT}_{1} ) & ( 17 )\end{matrix}$$

In the above formula, T₁ represents a data collection sampling cycle (details are explained below) and M represents the number of data (the number of data collection sampling points) for moving average processing including the present point).

(A Real-Time Frequency by the Gauge Voltage Group)

From the above calculation formula, a real-time frequency can be calculated using the following formula:

$$\begin{matrix}[ Math . 18 ] & \\ f = \{ \begin{matrix}\frac{α}{2 π} {f}_{s} & for α \geq 0 , \\ ( \frac{α}{2 π} + 1 ) {f}_{s} & for α < 0 , \\ \frac{{f}_{s}}{2 π} & for α = 0.\end{matrix} & ( 18 )\end{matrix}$$

In the above formula, f represents a real-time frequency and fₛ represents a gauge sampling frequency (details are explained below).

(Moving Average Processing of the Real-Time Frequency)

When the real-time frequency is calculated, to reduce the influence of noise, it is effective to perform moving average processing indicated by, for example, the following formula.

$$\begin{matrix}[ Math . 19 ] & \\ f = \frac{1}{M} {\sum }_{k = 0}^{M - 1} f ( t - {kT}_{1} ) & ( 19 )\end{matrix}$$

In the above formula, T₁ represents a data collection sampling cycle and M represents the number of data (the number of data collection sampling points) for the moving average processing including the present point.

(A Definition and a Calculation Formula (a First Calculation Formula) of the Gauge Voltage)

The inventor of the present application has found out the following formula as a calculation formula representing a square value of the gauge voltage according to “a vector product space diagram of the gauge voltage group” shown in FIG. 4 and substituted a related product of a real number multiplication table in the calculation formula and performed formula transformation.

$$\begin{matrix}[ Math . 20 ] & \\ \begin{matrix}{V}_{g}^{2} = {v}_{12}^{2} - {v}_{13} {v}_{11} \\ = \frac{1}{2} {V}^{2} [ cos ( 2 ω t ) + 1 - cos ( 2 ω t ) - cos 2 α ] \\ = \frac{1}{2} {V}^{2} ( 1 - cos 2 α ) \\ = {V}^{2} {sin}^{2} α\end{matrix} & ( 20 )\end{matrix}$$

According to the above formula, the gauge voltage value can be calculated using the following formula:

$$\begin{matrix}[ Math . 21 ] & \\ {V}_{g} = \{ \begin{matrix}V sin α & for α \geq 0 , \\ - V sin α & for α < 0.\end{matrix} & ( 21 )\end{matrix}$$

(Separation of the Data Collection Sampling Frequency and the Gauge Sampling Frequency)

Incidentally, as in Patent Literature 3 and the like, when accuracy of measurement is improved, it is a basic idea to reduce a sampling cycle (increase a sampling frequency) to increase the number of data and calculate, using the increased continuous data, various alternating-current electric quantities including a frequency coefficient. However, in a method of simply increasing the number of data, it is anticipated that the rotation phase angle also decreases according to the increase in the number of data and, when harmonic noise is large, a calculation result is affected by the harmonic noise and fluctuates and calculation accuracy is not improved. Therefore, the present invention has introduced a concept of the gauge sampling cycle T (the gauge sampling frequency fₛ) and the data collection sampling cycle T₁ (the data collection sampling frequency f₁) to make it possible to reduce the influence of the harmonic noise while maintaining a preferred value of the rotation phase angle such that a value of the rotation phase angle does not decrease even when data necessary for calculation is increased.

FIG. 5 is a diagram for explaining a relation between the gauge sampling cycle T and the data collection sampling cycle T₁. In FIG. 5, there is a relation indicated by the following formula between the gauge sampling frequency fₛ (the gauge sampling frequency T) and the data collection sampling frequency f₁ (the data collection sampling cycle T₁).

$$\begin{matrix}[ Math . 22 ] & \\ {f}_{s} = \frac{1}{T} = \frac{1}{{nT}_{1}} = \frac{1}{n} {f}_{1} & ( 22 )\end{matrix}$$

In the above formula, n represents a positive integer. In an example shown in FIG. 5, n=4.

In FIG. 5, a member of a gauge voltage group (a gauge voltage group 1) at the present point (time t) is as follows:

[Math. 23]

v₁(t),v₁(t−T),v₁(t−2T) (23)

A member of a gauge voltage group (a gauge voltage group 2) T₁ time before the present time (time t−T₁) is as follows:

[Mat. 24]

v₁(t−T₁),v₁(t−T−T₁),v₁(t−T−2T−T₁) (24)

As it is understood from FIG. 5, whereas an interval of the gauge voltage groups (an interval of the gauge voltage group 1 and the gauge voltage group 2) is the data collection sampling cycle T₁, an interval of the members forming the gauge voltage groups is the gauge sampling cycle T. That is, by introducing the concept of the gauge sampling cycle T (the gauge sampling frequency fₛ) and the data collection sampling cycle T₁ (the data collection sampling frequency f₁), it is possible to increase data necessary for calculation and suppress the influence of the harmonic noise while maintaining a suitable rotation phase angle α.

If the concept of the negative number rotation phase angle proposed in this application is used in addition to this concept, an effect equivalent to the effect of further increasing the data collection sampling frequency f₁ to a double is obtained. Note that, actually, it goes without saying that an appropriate data collection sampling frequency and an appropriate gauge sampling frequency are selected as appropriate according to a demand of a system.

Note that, if the data collection sampling frequency can be set as high as possible (e.g., in an international and standard protection relay apparatus, 4 kilohertz is recommended) according to selection of hardware taking into account cost performance, an output of a calculation result can be performed at high speed and, by using moving average processing for an output result as well, it is possible to greatly reduce the influence of the harmonic noise.

In this way, by introducing the concept of the processing in which the data collection sampling frequency and the gauge sampling frequency are distinguished, it is possible to suppress disturbance (small disturbance) always present in the power system.

(Moving Average Processing of the Gauge Voltage)

As in the case of the rotation phase angle and the real-time frequency, when the gauge voltage is calculated, to reduce the influence of noise, it is effective to perform moving average processing indicated by, for example, the following formula:

$$\begin{matrix} [ Math . 25 ] & \\ {V}_{g} ( t ) = \frac{1}{M} {\sum }_{k = 0}^{M - 1} \sqrt{{\{ Re [ {v}_{1} ( t - T - {kT}_{1} ) ] \}}^{2} - Re [ {v}_{1} ( t - {kT}_{1} ) ] \cdot Re [ {v}_{1} ( t - 2 T - {kT}_{1} ) ]} & ( 25 )\end{matrix}$$

In the above formula, T₁ represents a data collection sampling cycle and M represents the number of data collection sampling points including the present point.

(A Calculation Formula (a First Calculation Formula) of an Alternating-Current Voltage Amplitude by the Gauge Voltage Group)

If Formula (14), Formula (21), and the like are used, an alternating-current voltage amplitude V_{A} can be calculated using the following formula:

$$\begin{matrix}[ Math . 26 ] & \\ {V}_{A} = \{ \begin{matrix}\frac{{V}_{g}}{sin α} = \frac{{V}_{g}}{\sqrt{1 - {f}_{c}^{2}}} & for α \geq 0 , \\ \frac{- {V}_{g}}{sin α} = \frac{{V}_{g}}{\sqrt{1 - {f}_{c}^{2}}} & for α < 0.\end{matrix} & ( 26 )\end{matrix}$$

(A Moving Average of the Alternating-Current Voltage Amplitude)

Like other electric quantities, when the alternating-current voltage amplitude is calculated, to reduce the influence of noise, it is effective to perform moving average processing indicated by, for example, the following formula:

$$\begin{matrix}[ Math . 27 ] & \\ V = \frac{1}{M} {\sum }_{k = 0}^{M - 1} {V}_{A} ( t - {kT}_{1} ) & ( 27 )\end{matrix}$$

(Another Calculation Formula (a Second Calculation Formula) Concerning the Gauge Voltage)

The inventor of the present application has found out the following formula different from Formula (20) as another calculation formula concerning the gauge voltage on the basis of “the vector product space diagram of the gauge voltage group” shown in FIG. 4, and substituted the related product of the real number multiplication table shown in Table 2 in the formula, and performed formula transformation:

$$\begin{matrix}[ Math . 28 ] & \\ \begin{matrix}{V}_{g}^{2} = \frac{{v}_{11}^{2} + {v}_{13}^{2}}{2} - {v}_{12}^{2} cos 2 α \\ = \frac{1}{2} {V}^{2} [ cos ( 2 ω t ) cos 2 α + 1 - cos ( 2 ω t ) cos 2 α - cos 2 α ] \\ = \frac{1}{2} {V}^{2} ( 1 - cos 2 α ) \\ = {V}^{2} {sin}^{2} α\end{matrix} & ( 28 )\end{matrix}$$

Formula (28) is a calculation formula of a square value of the gauge voltage. The gauge voltage can also be calculated using the following formula:

$$\begin{matrix}[ Math . 29 ] & \\ {V}_{g} = \sqrt{\frac{{v}_{11}^{2} + {v}_{13}^{2}}{2} - {v}_{12}^{2} ( 2 {f}_{c}^{2} - 1 )} & ( 29 )\end{matrix}$$

The above calculation formula is formed by only square calculation of an input variable and is advantageous for computer data processing. According to Formula (25), a calculation formula of moving average processing is proposed.

$$\begin{matrix} [ Math . 30 ] & \\ {V}_{g} ( t ) = \frac{1}{M} {\sum }_{k = 0}^{M - 1} \sqrt{\frac{\begin{matrix}{\{ Re [ {v}_{1} ( t - {kT}_{1} ) ] \}}^{2} + \\ {\{ Re [ {v}_{1} ( t - 2 T - {kT}_{1} ) ] \}}^{2}\end{matrix}}{2} - {\{ Re [ {v}_{1} ( t - T - {kT}_{1} ) ] \}}^{2} ( 2 {f}_{c}^{2} - 1 )} & ( 30 )\end{matrix}$$

(Another Calculation Formula (a Second Calculation Formula) Concerning the Alternating-Current Voltage Amplitude)

The inventor of the present application has also attempted derivation of another calculation formula concerning the alternating-current voltage amplitude. Specifically, the inventor of the present application has found out the following formula and the formula following the following formula representing an addition and a subtraction of members in the gauge voltage group, substituted the related product of the real number multiplication table in the respective formulas, and performed formula transformation:

$$\begin{matrix}[ Math . 31 ] & \\ \begin{matrix}{v}_{11} + {v}_{13} + 2 {v}_{12} = V [ cos ( ω t + α ) + cos ( ω t - α ) + 2 cos ( ω t ) ] \\ = 2 V ( cos α + 1 ) cos ( ω t ) \\ = 4 V {cos}^{2} \frac{α}{2} cos ( ω t )\end{matrix} & ( 31 ) \\ [ Math . 32 ] & \\ \begin{matrix}{v}_{11} - {v}_{13} = V [ cos ( ω t + α ) - cos ( ω t - α ) ] \\ = - 2 V sin α sin ( ω t )\end{matrix} & ( 32 )\end{matrix}$$

According to the two formulas, a calculation formula of the alternating-current voltage amplitude is obtained as indicated by the following formula:

$$\begin{matrix}[ Math . 33 ] & \\ \begin{matrix}V = \sqrt{{( \frac{{v}_{11} + {v}_{13} + 2 {v}_{12}}{4 {cos}^{2} \frac{α}{2}} )}^{2} + {( \frac{{v}_{11} - {v}_{13}}{2 sin α} )}^{2}} \\ = \frac{1}{2 \sqrt{1 + {f}_{c}}} \sqrt{\frac{{( {v}_{11} + {v}_{13} + 2 {v}_{12} )}^{2}}{1 + {f}_{c}} + \frac{{( {v}_{11} - {v}_{13} )}^{2}}{1 - {f}_{c}}}\end{matrix} & ( 33 )\end{matrix}$$

A calculation formula for the moving average processing can be represented by the following formula:

$$\begin{matrix}[ Math . 34 ] & \\ V ( t ) = \frac{1}{2 M \sqrt{1 + {f}_{c}}} {\sum }_{k = 0}^{M - 1} \sqrt{\frac{{\{ {v}_{add} ( t , k ) \}}^{2}}{1 + {f}_{c}} + \frac{{\{ {v}_{sub} ( t , k ) \}}^{2}}{1 + {f}_{c}}} & ( 34 )\end{matrix}$$

Note that a calculation formula of v_{add}(t,k) and v_{sub}(t,k) in a square root sign of the above formula is as indicated by the following formula:

$$\begin{matrix}[ Math . 35 ] & \\ \{ \begin{matrix}{v}_{add} ( t , k ) = \begin{matrix}Re [ {v}_{1} ( t - {kT}_{1} ) ] + Re [ {v}_{1} ( t - 2 T - {kT}_{1} ) ] + \\ 2 Re [ {v}_{1} ( t - T - {kT}_{1} ) ]\end{matrix} \\ {v}_{sub} ( t , k ) = Re [ {v}_{1} ( t - {kT}_{1} ) ] - Re [ {v}_{1} ( t - 2 T - {kT}_{1} ) ]\end{matrix} & ( 35 )\end{matrix}$$

As explained above, various invariants have been found according to the multiplication table of the gauge voltage group and the arithmetic operation (the addition, the subtraction, etc.) for the gauge voltage group.

In the following explanation, a symmetric voltage group that can be calculated and output at higher speed by reducing the number of voltage rotation vectors, which are constituent members of the gauge voltage group, by one is proposed. Note that the symmetric voltage group, that is, the symmetric voltage group consisting of two voltage rotation vectors obtained by reducing the number of voltage rotation vectors by one is referred to as rotation voltage group.

(A Rotation Voltage Group on a Complex Plane)

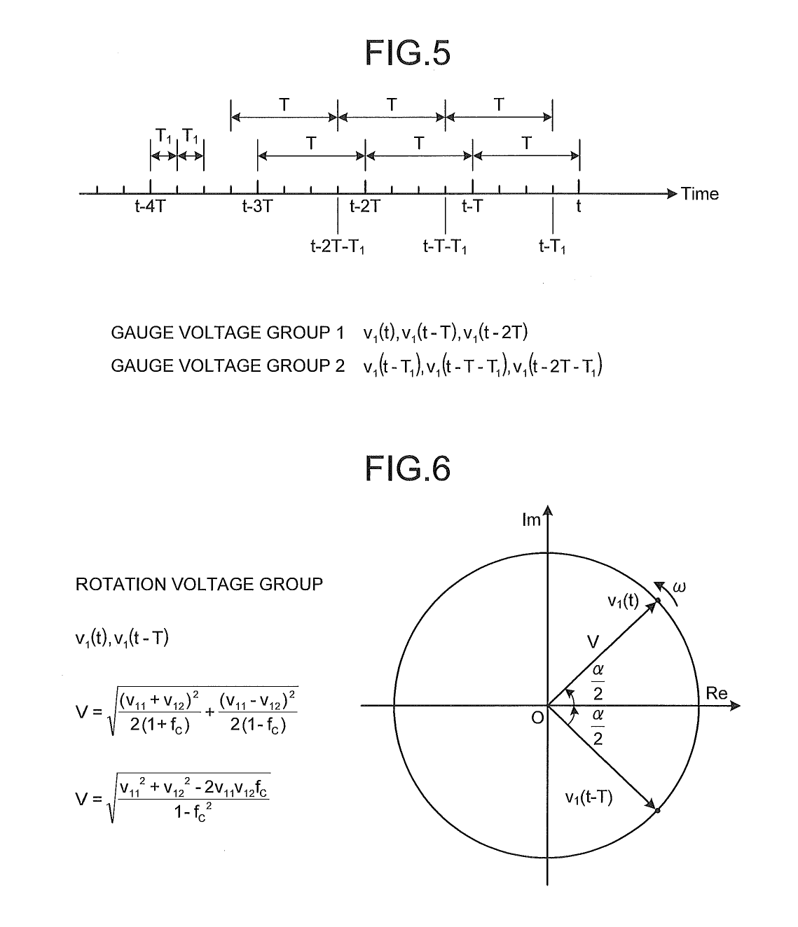

FIG. 6 is a diagram of a rotation voltage group on a complex plane. Two voltage rotation vectors on the complex plane shown in FIG. 6 can be represented by the following formula:

$$\begin{matrix}[ Math . 36 ] & \\ \{ \begin{matrix}{v}_{1} ( t ) = V {e}^{j ( ω t + \frac{α}{2} )} \\ {v}_{1} ( t - T ) = V {e}^{j ( ω t - \frac{α}{2} )}\end{matrix} & ( 36 )\end{matrix}$$

In the above formula, V represents an alternating-current voltage amplitude, ω represents rotation angular velocity, T represents the gauge sampling cycle, and α represents a rotation phase angle at T. In FIG. 6, two voltage rotation vectors v₁(t) and v₁(t−T) have symmetry. Even at another time or even if the two voltage rotation vectors are present in other places, the rotation phase angle α between the two voltage rotation vectors does not change. That is, the rotation voltage group is also a structure having a characteristic of rotation invariance like the gauge voltage group explained above.

(A Vector Multiplication Table of the Rotation Voltage Group)

To check an invariant of the rotation voltage group, a vector multiplication table of the rotation voltage group shown in Table 3 below is established.

TABLE 3
A vector group table of the rotation voltage group

| x | v₁(t) | v₁(t − T) |
|---|---|---|
| v₁(t) | v₁²(t) | v₁(t − T)v₁(t) |
| v₁(t − T) | v₁(t)v₁(t − T) | v₁²(t − T) |

Voltage rotation vectors shown in the vector multiplication table are complex number state variables. An “×” sign in the table means that multiplication of an element on a table side and an element at a table top is performed. In this case, product elements of the vector multiplication table of the rotation voltage group can be represented as indicated by the following formula:

$$\begin{matrix}[ Math . 37 ] & \\ \{ \begin{matrix}{v}_{1}^{2} ( t ) = {V}^{2} {e}^{j ( 2 ω t + α )} \\ {v}_{1} ( t ) {v}_{1} ( t - T ) = {V}^{2} {e}^{j ( 2 ω t )} \\ {v}_{1}^{2} ( t - T ) = {V}^{2} {e}^{j ( 2 ω t - α )}\end{matrix} & ( 37 )\end{matrix}$$

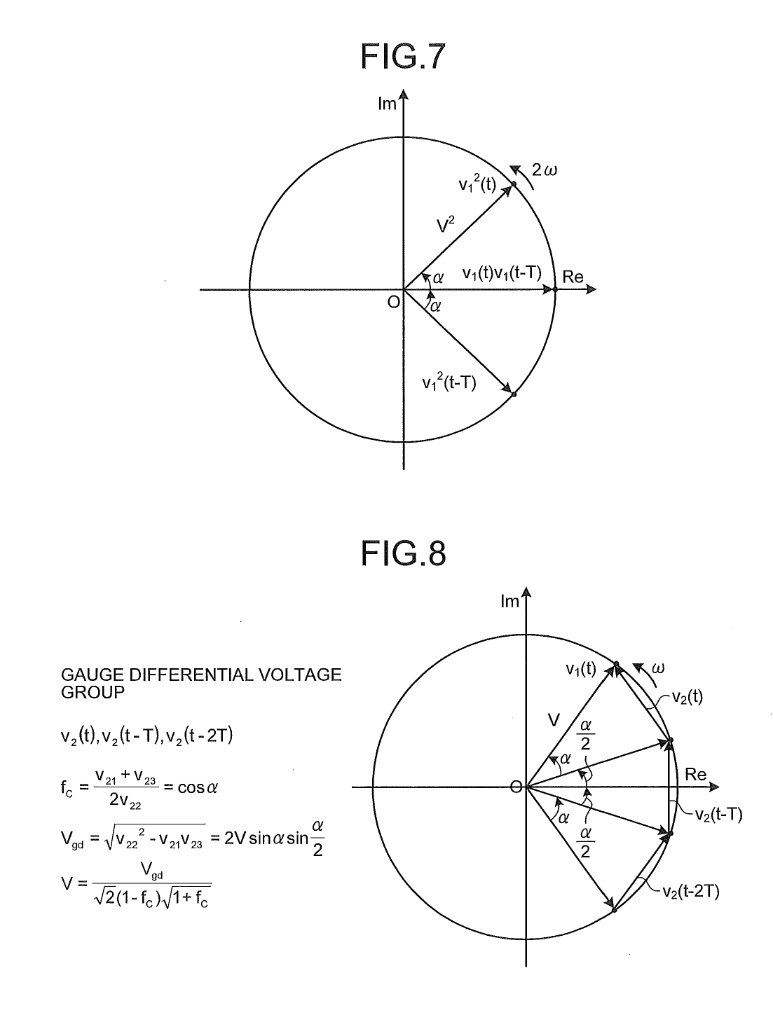

A figure in which vector product elements based on the above formula are shown on a complex plane is FIG. 7. A space generated by product calculation of two vectors is referred to as vector product space. Symmetry intrinsic in an alternating-current sine wave can be seen using the vector product space. In the vector product space, vector product elements rotate counterclockwise at angular velocity of 2ω.

Note that, as shown in FIG. 7, a set of v₁²(t) and v₁²(t−T) has a phase difference α with respect to an intermediate axis (in the example shown in FIG. 4, the real axis (Re axis)). As explained in detail below, a voltage amplitude can be calculated by the set.

(A Real Number Multiplication Table of the Rotation Voltage Group)

To derive a calculation formula of an invariant of the rotation voltage group, a real number multiplication table of the rotation voltage group shown in Table 4 below is established. Note that, as explained above, as a voltage instantaneous value in the real number multiplication table, a real number part of a voltage rotation vector can be used or an imaginary number part of the voltage rotation vector can be used.

TABLE 4
A real number group table of the rotation voltage group

| x | v₁₁ | v₁₂ |
|---|---|---|
| v₁₁ | v²₁₁ | v₁₂v₁₁ |
| v₁₂ | v₁₁v₁₂ | v²₁₂ |

The real number multiplication table of the rotation voltage group is explained. First, instantaneous value elements, which are constituent elements of the set shown in Table 4, can be represented by the following formula:

$$\begin{matrix}[ Math . 38 ] & \\ \{ \begin{matrix}{v}_{11} = Re [ {v}_{1} ( t ) ] = V cos ( ω t + \frac{α}{2} ) \\ {v}_{12} = Re [ {v}_{1} ( t - T ) ] = V cos ( ω t - \frac{a}{2} )\end{matrix} & ( 38 )\end{matrix}$$

According to the above formula, the product elements shown in Table 4 can be represented as indicated by the following formula:

$$\begin{matrix}[ Math . 39 ] & \\ \{ \begin{matrix}{v}_{11}^{2} = {V}^{2} {cos}^{2} ( ω t + \frac{α}{2} ) \\ {v}_{12} {v}_{11} = {V}^{2} cos ( ω t + \frac{a}{2} ) cos ( ω t - \frac{α}{2} ) \\ {v}_{12}^{2} = {V}^{2} {cos}^{2} ( ω t - \frac{α}{2} )\end{matrix} & ( 39 )\end{matrix}$$

A calculation formula of various invariants related to the rotation voltage group is explained using the product elements of the real number multiplication table of the rotation voltage group.

(A Calculation Formula (a First Calculation Formula) of an Alternating-Current Voltage Amplitude by the Rotation Voltage Group)

As in the case of the gauge voltage group, formula transformation is performed by calculation representing an addition and a subtraction of members.

$$\begin{matrix}[ Math . 40 ] & \\ \{ \begin{matrix}{v}_{11} + {v}_{12} = 2 V cos \frac{α}{2} cos ( ω t ) \\ {v}_{11} - {v}_{12} = - 2 V sin \frac{a}{2} sin ( ω t )\end{matrix} & ( 40 )\end{matrix}$$

According to these two formulas, a calculation formula of an alternating-current voltage amplitude is obtained as indicated by the following formula:

$$\begin{matrix} [ Math . 41 ] & \\ V = \sqrt{\frac{{( {v}_{11} + {v}_{12} )}^{2}}{4 {cos}^{2} \frac{α}{2}} + \frac{{( {v}_{11} - {v}_{12} )}^{2}}{4 {sin}^{2} \frac{α}{2}}} = \sqrt{\frac{{( {v}_{11} + {v}_{12} )}^{2}}{2 ( 1 + {f}_{c} )} + \frac{{( {v}_{11} - {v}_{12} )}^{2}}{2 ( 1 - {f}_{c} )}} & ( 41 )\end{matrix}$$

A calculation formula for moving average processing can be represented by the following formula:

$$\begin{matrix}[ Math . 42 ] & \\ V ( t ) = \frac{1}{M} {\sum }_{k = 0}^{M - 1} \sqrt{\frac{{\{ {v}_{add} ( t , k ) \}}^{2}}{2 ( 1 + {f}_{c} )} + \frac{{\{ {v}_{sub} ( t , k ) \}}^{2}}{2 ( 1 - {f}_{c} )}} & ( 42 )\end{matrix}$$

Note that a calculation formula of v_{add}(t,k) and v_{sub}(t,k) in a square root sign of the above formula is as indicated by the following formula:

$$\begin{matrix}[ Math . 43 ] & \\ \{ \begin{matrix}{v}_{add} ( t , k ) = Re [ {v}_{1} ( t - {kT}_{1} ) ] + Re [ {v}_{1} ( t - T - {kT}_{1} ) ] \\ {v}_{sub} ( t , k ) = Re [ {v}_{1} ( t - {kT}_{1} ) ] - Re [ {v}_{1} ( t - T - {kT}_{1} ) ]\end{matrix} & ( 43 )\end{matrix}$$

(A Calculation Formula (a Second Calculation Formula) of an Alternating-Current Voltage Amplitude by the Rotation Voltage Group)

The inventor of the present application has found out the following formula for calculating an alternating-current voltage amplitude, substituted the related product of the real number multiplication table in the formula, and performed formula transformation.

$$\begin{matrix} [ Math . 44 ] & \\ {v}_{11}^{2} + {v}_{12}^{2} - 2 {v}_{12} {v}_{11} cos α = {V}^{2} [ cos ( 2 ω t ) cos α + 1 - cos ( 2 ω t ) cos α - {cos}^{2} α ] = {V}^{2} {sin}^{2} α & ( 44 )\end{matrix}$$

According to the above formula, a calculation formula of an alternating-current voltage amplitude is obtained as indicated by the following formula:

$$\begin{matrix} [ Math . 45 ] & \\ V = \sqrt{\frac{{v}_{11}^{2} + {v}_{12}^{2} - 2 {v}_{12} {v}_{11} cos α}{{sin}^{2} α}} = \sqrt{\frac{{v}_{11}^{2} + {v}_{12}^{2} - 2 {v}_{12} {v}_{11} {f}_{c}}{1 - {f}_{c}^{2}}} & ( 45 )\end{matrix}$$

Similarly, a calculation formula for moving average processing can be represented by the following formula:

$$\begin{matrix}[ Math . 46 ] & \\ V ( t ) = \frac{1}{M} {\sum }_{k = 0}^{M - 1} \sqrt{\frac{{v}_{add 2} ( t , k )}{1 - {f}_{c}^{2}}} & ( 46 )\end{matrix}$$

Note that a calculation formula of v_{add2}(t,k) in a square root sign of the above formula is as indicated by the following formula:

[Math. 47]

V_{add2}(t,k)={Re[v₁(t−kT₁)]}²+{Re[v₁(t−T−kT₁)]}²−2f_{c}×{Re[v₁(t−kT₁)]}×{Re[v₁(t−T−kT₁)]} (47)

(A Symmetry Index of the Rotation Voltage Group)

The following formula is proposed as a symmetry index of the rotation voltage group.

$$\begin{matrix}[ Math . 48 ] & \\ \vert \frac{{V}_{1} - {V}_{2}}{{V}_{1}} \vert > d {V}_{SET} & ( 48 )\end{matrix}$$

In the above formula, V₁ represents a calculation result by the first calculation formula of an alternating-current voltage amplitude, V₂ represents a calculation result by the second calculation formula of an alternating-current voltage amplitude, and dV_{SET} represents a setting value. When the above formula is satisfied, symmetry of the rotation voltage group is broken. Therefore, at a point in time when the symmetry is broken, a calculation value before the break of the symmetry is latched. On the other hand, when the above formula is not satisfied, it is determined that the symmetry is not broken. A calculation value of the present symmetric group is used.

(A Gauge Differential Voltage Group on a Complex Plane)

FIG. 8 is a diagram of a gauge differential voltage group on a complex plane in which a positive number rotation phase angle is used. Three differential voltage rotation vectors on the complex plane shown in FIG. 8 can be represented by the following formula:

$$\begin{matrix}[ Math . 49 ] & \\ \{ \begin{matrix}{v}_{2} ( t ) = V {e}^{j ( ω t + \frac{3 α}{2} )} - V {e}^{j ( ω t + \frac{α}{2} )} \\ {v}_{2} ( t - T ) = V {e}^{j ( ω t + \frac{α}{2} )} - V {e}^{j ( ω t - \frac{α}{2} )} \\ {v}_{2} ( t - 2 T ) = V {e}^{j ( ω t - \frac{α}{2} )} - V {e}^{j ( ω t - \frac{3 α}{2} )}\end{matrix} & ( 49 )\end{matrix}$$

In the above formula, V represents an alternating-current voltage amplitude, ω represents rotation angular velocity, T represents the gauge sampling cycle, and a represents a rotation phase angle at T. In three differential voltage rotation vectors v₂(t), v₂(t−T), and v₂(t−2T) shown in FIG. 8, two differential voltage rotation vectors v₂(t) and V₂(t−2T) located on both sides have symmetry with respect to the differential voltage rotation vector V₂(t−T) located in the center. Further, at another time, even if the three differential voltage rotation vectors rotate and are present in other places, the rotation phase angle α, which is a phase angle difference between any two of the voltage rotation vectors, does not change. Therefore, the gauge differential voltage group has rotation invariance same as the rotation invariance of the gauge voltage group. The three differential voltage rotation vectors is defined as a gauge differential voltage group.

(Negative Number Rotation Phase Angle)

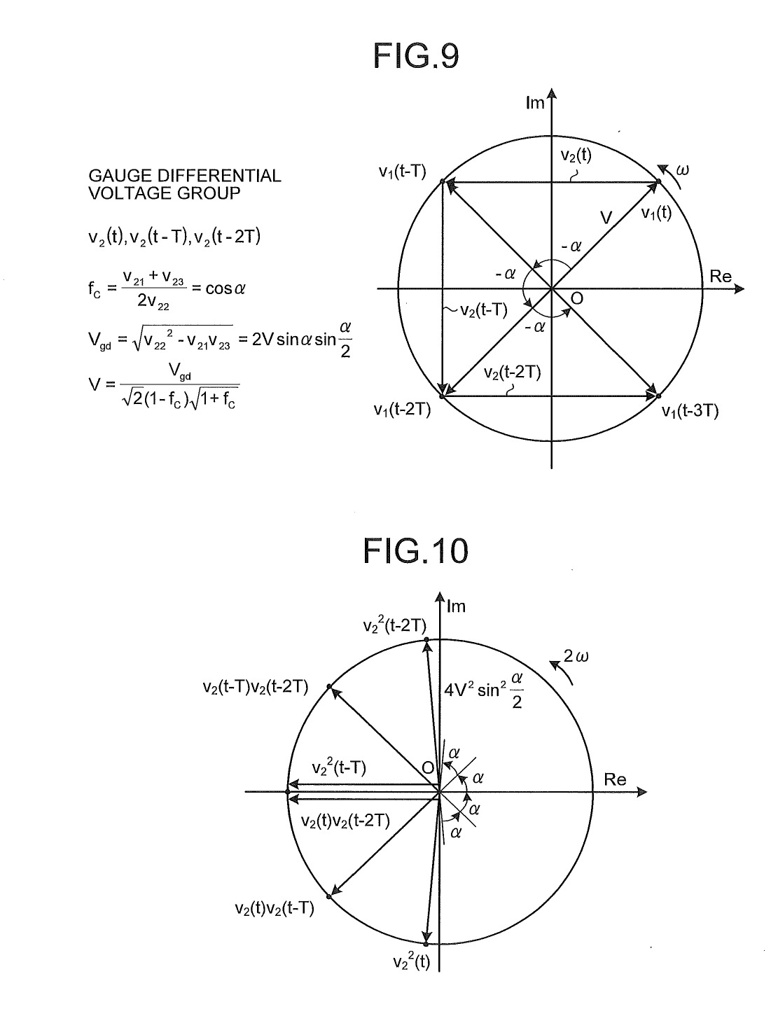

FIG. 9 is a diagram of a gauge differential voltage group on a complex plane in which a negative number rotation phase angle is used. When a rotation phase angle between differential voltage rotation vectors is larger than 180 degrees, as in the gauge voltage group, a negative number rotation phase angle is used.

As shown in FIG. 9, there is symmetry between members of the gauge differential voltage group and rotation invariance is present even if the rotation phase angle of the gauge differential voltage group is minus.

(A Vector Multiplication Table of the Gauge Differential Voltage Group)

To check an invariant of the gauge differential voltage group, a vector multiplication table of the gauge voltage group shown in Table 5 below is established.

TABLE 5
A vector group table of the gauge differential voltage group

| x | v₂(t) | v₂(t − T) | v₂(t − 2T) |
|---|---|---|---|
| v₂(t) | v₂²(t) | v₂(t − T)v₂(t) | v₂(t − 2T)v₂(t) |
| v₂(t − T) | v₂(t)v₂(t − T) | v₂²(t − T) | v₂(t − 2T)v₂(t − T) |
| v₂(t − 2T) | v₂(t)v₂(t − 2T) | v₂(t − T)v₂(t − 2T) | v₂²(t − 2T) |

Differential voltage rotation vectors shown in the vector multiplication table are complex number state variables. An “×” sign in the table means that multiplication of an element on a table side and an element at a table top is performed. In this case, product elements of the vector multiplication table of the gauge differential voltage group can be represented as indicated by the following formula:

$$\begin{matrix}[ Math . 50 ] & \\ \{ \begin{matrix}{v}_{2}^{2} ( t ) = {V}^{2} [ {e}^{j ( 2 ω t + 3 α )} + {e}^{j ( 2 ω t + α )} - 2 {e}^{j ( 2 ω t + 2 α )} ] \\ {v}_{2} ( t ) {v}_{2} ( t - T ) = {V}^{2} [ {e}^{j ( 2 ω t + 2 α )} + {e}^{j ( 2 ω t )} - 2 {e}^{j ( 2 ω t + α )} ] \\ {v}_{2} ( t ) {v}_{2} ( t - 2 T ) = {V}^{2} [ {e}^{j ( 2 ω + α )} + {e}^{j ( 2 ω t - α )} - 2 {e}^{j ( 2 ω t )} ] \\ {v}_{2}^{2} ( t - T ) = {V}^{2} [ {e}^{j ( 2 ω t + α )} + {e}^{j ( 2 ω t - α )} - 2 {e}^{j ( 2 ω t )} ] \\ {v}_{2} ( t - T ) {v}_{2} ( t - 2 T ) = {V}^{2} [ {e}^{j ( 2 ω t )} + {e}^{j ( 2 ω t - 2 α )} - 2 {e}^{j ( 2 ω t - α )} ] \\ {v}_{2}^{2} ( t - 2 T ) = {V}^{2} [ {e}^{j ( 2 ω t - 3 α )} + {e}^{j ( 2 ω t - α )} - 2 {e}^{j ( 2 ω t - 2 α )} ]\end{matrix} & ( 50 )\end{matrix}$$

If calculation of the right side of the above formula is advanced, the formula can be simplified as indicated by the following formula:

$$\begin{matrix}[ Math . 51 ] & \\ \{ \begin{matrix}{v}_{2}^{2} ( t ) = 4 {V}^{2} {sin}^{2} \frac{α}{2} {e}^{j ( 2 ω t + 2 α - π )} \\ {v}_{2} ( t ) {v}_{2} ( t - T ) = 4 {V}^{2} {sin}^{2} \frac{α}{2} {e}^{j ( 2 ω t + α - π )} \\ {v}_{2} ( t ) {v}_{2} ( t - 2 T ) = 4 {V}^{2} {sin}^{2} \frac{α}{2} {e}^{j ( 2 ω t - π )} \\ {v}_{2}^{2} ( t - T ) = 4 {V}^{2} {sin}^{2} \frac{α}{2} {e}^{j ( 2 ω t - π )} \\ {v}_{2} ( t - T ) {v}_{2} ( t - 2 T ) = 4 {V}^{2} {sin}^{2} \frac{α}{2} {e}^{j ( 2 ω t - α - π )} \\ {v}_{2}^{2} ( t - 2 T ) = 4 {V}^{2} {sin}^{2} \frac{α}{2} {e}^{j ( 2 ω t - 2 α - π )}\end{matrix} & ( 51 )\end{matrix}$$

A figure in which vector product elements based on the above formula are represented on a complex plane is FIG. 10. The vector product elements rotate counterclockwise at angular velocity of 2ω. Three kinds of symmetry are selected and explained below.

A first set having symmetry is a set of v₂²(t−T) and v₂(t)v₂(t−2T) located on an intermediate axis (in an example shown in FIG. 10, a real axis (Re axis)) of rotation vectors. As indicated by the following formula, results of vector products v₂²(t−T) and v₂(t)v₂(t−2T) are equal.

$$\begin{matrix}[ Math . 52 ] & \\ {v}_{2}^{2} ( t - T ) = {v}_{2} ( t ) {v}_{2} ( t - 2 T ) = 4 {V}^{2} {sin}^{2} \frac{α}{2} {e}^{j ( 2 ω t - π )} & ( 52 )\end{matrix}$$

As it is evident from a calculation formula described below, a gauge differential voltage proposed before (e.g., Patent Literature 3) is formed by these sets.

A second set having symmetry is a set of v₂(t)v₂(t−T) and v₂(t−T)v₂(t−2T). v₂(t)v₂(t−T) and v₂ (t−T)v₂(t−2T) have a phase difference α with respect to the intermediate axis. According to a calculation formula described below, a frequency coefficient can be formed by this set.

A third set having symmetry is a set of v₂²(t) and v₂²(t−2T). v₂²(t) and v₂²(t−2T) have a phase difference 2α with respect to the intermediate axis. According to a calculation formula described below, a gauge differential voltage by only a square formula can be formed by this set and a rotation vector v₂(t−T) in the middle.

(A Real Number Multiplication Table of the Gauge Differential Voltage Group)

To derive a calculation formula of an invariant of the gauge differential voltage group, a real number multiplication table of the gauge differential voltage group shown in Table 6 below is established.

TABLE 6
A real number group table of the gauge differential voltage group

| x | v₂₁ | v₂₂ | v₂₃ |
|---|---|---|---|
| v₂₁ | v²₂₁ | v₂₂v₂₁ | v₂₃v₂₁ |
| v₂₂ | v₂₁v₂₂ | v²₂₂ | v₂₃v₂₂ |
| v₂₃ | v₂₁v₂₃ | v₂₂v₂₃ | v²₂₃ |

The real number multiplication table of the gauge differential voltage group is explained. First, instantaneous value elements, which are constituent elements of the set shown in Table 6, can be represented by the following formula:

$$\begin{matrix} [ Math . 53 ] & \\ \{ \begin{matrix}{v}_{21} = Re [ {v}_{2} ( t ) ] = V [ \begin{matrix}cos ( ω t + \frac{3 α}{2} ) - \\ cos ( ω t + \frac{α}{2} )\end{matrix} ] = - 2 V sin \frac{α}{2} sin ( ω t + α ) \\ {v}_{22} = Re [ {v}_{2} ( t - T ) ] = V [ \begin{matrix}cos ( ω t + \frac{α}{2} ) - \\ cos ( ω t - \frac{α}{2} )\end{matrix} ] == - 2 V sin \frac{α}{2} sin ( ω t ) \\ {v}_{23} = Re [ {v}_{2} ( t - 2 T ) ] = V [ \begin{matrix}cos ( ω t - \frac{α}{2} ) - \\ cos ( ω t - \frac{3 α}{2} )\end{matrix} ] = - 2 V sin \frac{α}{2} sin ( ω t - α )\end{matrix} & ( 53 )\end{matrix}$$

In the above formula, “Re” indicates a real number part of a complex number. According to the above formula, product elements shown in Table 6 can be represented as indicated by the following formula:

$$\begin{matrix}[ Math . 54 ] & \\ \{ \begin{matrix}{v}_{21}^{2} = 4 {V}^{2} {sin}^{2} \frac{α}{2} {sin}^{2} ( ω t + α ) \\ {v}_{22} {v}_{21} = 4 {V}^{2} {sin}^{2} \frac{α}{2} sin ( ω t + α ) sin ( ω t ) \\ {v}_{23} {v}_{21} = 4 {V}^{2} {sin}^{2} \frac{α}{2} sin ( ω t - α ) sin ( ω t + α ) \\ {v}_{22}^{2} = 4 {V}^{2} {sin}^{2} \frac{α}{2} {sin}^{2} ( ω t ) \\ {v}_{23} {v}_{22} = 4 {V}^{2} {sin}^{2} \frac{α}{2} sin ( ω t - α ) sin ( ω t ) \\ {v}_{23}^{2} = 4 {V}^{2} {sin}^{2} \frac{α}{2} {sin}^{2} ( ω t - α )\end{matrix} & ( 54 )\end{matrix}$$

A calculation formula of various invariants related to the gauge differential voltage group is explained using the product elements of the real number multiplication table of the gauge differential voltage group.

(A Calculation Formula of a Frequency Coefficient by the Gauge Differential Voltage Group)

A calculation formula of a frequency coefficient by the gauge differential voltage group is explained below. To derive a relation between a calculation formula of a frequency coefficient and a real number multiplication table, the inventor of the present application has performed formula transformation shown below and substituted the product elements of the real number multiplication table shown in Table 6 in the transformed formula with reference to the space vector diagram of the gauge differential voltage group shown in FIG. 10.

$$\begin{matrix}[ Math . 55 ] & \\ \begin{matrix}{f}_{c} = \frac{{v}_{21} + {v}_{23}}{2 {v}_{22}} \\ = \frac{{v}_{22} {v}_{21} + {v}_{23} {v}_{22}}{2 {v}_{22}^{2}} \\ = \frac{4 {V}^{2} {sin}^{2} \frac{α}{2} [ sin ( ω t + α ) sin ( ω t ) + sin ( ω t - α ) sin ( ω t ) ]}{4 {V}^{2} {sin}^{2} \frac{α}{2} {sin}^{2} ( ω t )} \\ = cos α\end{matrix} & ( 55 )\end{matrix}$$

As it is evident from the formula transformation, the frequency coefficient f_{c} of the gauge differential voltage group can be calculated using the product elements of the real number multiplication table.

(A Symmetry Index of the Gauge Differential Voltage Group)

The following formula is proposed as a symmetry index of the gauge differential voltage group.

$$\begin{matrix}[ Math . 56 ] & \\ \vert {f}_{c} \vert = \vert \frac{{v}_{21} + {v}_{23}}{2 {v}_{22}} \vert > 1 & ( 56 )\end{matrix}$$

When the above formula is satisfied, the symmetry of the gauge differential voltage group established by v₂(t), v₂(t−T), and v₂(t−t2T) is broken. Therefore, at a point in time when the symmetry of the gauge differential voltage group is broken, a calculation value before the break of the symmetry is latched. On the other hand, when the above formula is not satisfied, it is determined that the symmetry is not broken. The present calculation value is used.

(A Rotation Phase Angle and a Real-Time Frequency by the Gauge Differential Voltage Group)

Calculation formulas of a rotation phase angle and a real-time frequency by the gauge differential voltage group are the same as the calculation formulas of a rotation phase angle and the real-time frequency by the gauge voltage group. Therefore, explanation of the calculation formulas is omitted.

(A Definition and a Calculation Formula (a First Calculation Formula) of the Gauge Differential Voltage)

The inventor of the present application has found out the following formula as a calculation formula representing a square value of the gauge differential voltage according to “a vector product space diagram of the gauge differential voltage group” shown in FIG. 10, substituted a related product of a real number multiplication table in the calculation formula, and performed formula transformation.

$$\begin{matrix}[ Math . 57 ] & \\ \begin{matrix}{V}_{gd}^{2} = {v}_{22}^{2} - {v}_{21} {v}_{23} \\ = 4 {V}^{2} {sin}^{2} \frac{α}{2} [ {sin}^{2} ( ω t ) - sin ( ω t - α ) sin ( ω t + α ) ] \\ = 4 {V}^{2} {sin}^{2} \frac{α}{2} [ {sin}^{2} ( ω t ) + \frac{1}{2} cos ( 2 ω t ) - \frac{1}{2} cos 2 α ] \\ = 4 {V}^{2} {sin}^{2} α {sin}^{2} \frac{α}{2}\end{matrix} & ( 57 )\end{matrix}$$

According to the above formula, the gauge differential voltage value can be calculated using the following formula described in Patent Literature 3 as well:

$$\begin{matrix}[ Math . 58 ] & \\ {V}_{gd} = 2 V sin α sin \frac{α}{2} & ( 58 )\end{matrix}$$

(Moving Average Processing of the Gauge Differential Voltage)

As in the case of the rotation phase angle, the real-time frequency, and the gauge voltage, when the gauge differential voltage is calculated, to reduce the influence of noise, it is effective to perform moving average processing indicated by, for example, the following formula:

$$\begin{matrix}[ Math . 59 ] & \\ {V}_{gd} ( t ) = \frac{1}{M} {\sum }_{k = 0}^{M - 1} \sqrt{\begin{matrix}{\{ Re [ {v}_{2} ( t - T - {kT}_{1} ) ] \}}^{2} - \\ Re [ {v}_{2} ( t - {kT}_{1} ) ] \cdot Re [ {v}_{2} ( t - 2 T - {kT}_{1} ) ]\end{matrix}} & ( 59 )\end{matrix}$$

In the above formula, T₁ represents a data collection sampling cycle and M represents the number of data collection sampling points including the present point.

(A Calculation Formula (a First Calculation Formula) of an Alternating-Current Voltage Amplitude by the Gauge Differential Voltage Group)

If Formula (58) is used, an alternating-current voltage amplitude V_{D} by the gauge differential voltage group can be calculated using the following formula:

$$\begin{matrix}[ Math . 60 ] & \\ \begin{matrix}{V}_{D} = \frac{{V}_{gd}}{2 sin αsin \frac{α}{2}} \\ = \frac{{V}_{gd}}{2 \sqrt{1 - {f}_{c}^{2}} \sqrt{\frac{1 - {f}_{c}}{2}}} \\ = \frac{\sqrt{2} {V}_{gd}}{2 ( 1 - {f}_{c} ) \sqrt{1 + {f}_{c}}}\end{matrix} & ( 60 )\end{matrix}$$

The gauge differential voltage is calculated by a difference of a voltage instantaneous value. Therefore, because the influence of a direct-current component in a voltage waveform is cancelled, high-speed and highly accurate measurement is possible.

(A Moving Average of the Alternating-Current Voltage Amplitude)

Like other electric quantities, when the alternating-current voltage amplitude is calculated, to reduce the influence of noise, it is effective to perform moving average processing indicated by, for example, the following formula:

$$\begin{matrix}[ Math . 61 ] & \\ V = \frac{1}{M} {\sum }_{k = 0}^{M - 1} {V}_{D} ( t - {kT}_{1} ) & ( 61 )\end{matrix}$$

(A Calculation Formula of an Alternating-Current Voltage Root Mean Square Value by the Gauge Differential Voltage Group)

In a power system, an alternating-current voltage root mean square value is often used. From the result explained above, an alternating-current voltage root mean square value Vᵣₘₛ can be calculated using the following formula:

$$\begin{matrix}[ Math . 62 ] & \\ {V}_{r m s} = \frac{V}{\sqrt{2}} = \frac{{V}_{gd }}{2 ( 1 - {f}_{c} ) \sqrt{1 + {f}_{c}}} & ( 62 )\end{matrix}$$

(Another Calculation Formula (a Second Calculation Formula) Concerning the Gauge Differential Voltage)

The inventor of the present application has found out the following formula different from Formula (57) as another calculation formula concerning the gauge differential voltage on the basis of “the vector product space diagram of the gauge differential voltage group” shown in FIG. 10, substituted the related product of the real number multiplication table shown in Table 6 in the formula, and performed formula transformation:

$$\begin{matrix}[ Math . 63 ] & \\ \begin{matrix}{V}_{gd} = \sqrt{\frac{{v}_{21}^{2} + {v}_{23}^{2}}{2} - {v}_{22}^{2} cos 2 α} \\ = \sqrt{2 {V}^{2} {sin}^{2} \frac{α}{2} [ \begin{matrix}{sin}^{2} ( ω t + α ) + {sin}^{2} ( ω t - α ) - \\ 2 {sin}^{2} ( ω t ) cos 2 α\end{matrix} ]} \\ = \sqrt{\begin{matrix}2 {V}^{2} {sin}^{2} \frac{α}{2} \\ [ 1 - cos ( 2 ω t ) cos 2 α - 2 {sin}^{2} ( ω t ) cos 2 α ]\end{matrix}} \\ = \sqrt{2 {V}^{2} {sin}^{2} \frac{α}{2} ( 1 - cos 2 α )} \\ = 2 V sin α sin \frac{α}{2}\end{matrix} & ( 63 )\end{matrix}$$

Formula (63) is a calculation formula of a square value of the gauge differential voltage. The gauge differential voltage can also be used using the following formula:

$$\begin{matrix}[ Math . 64 ] & \\ {V}_{gd} = \sqrt{\frac{{v}_{21}^{2} + {v}_{23}^{2}}{2} - {v}_{22}^{2} ( 2 {f}_{C}^{2} - 1 )} & ( 64 )\end{matrix}$$

Note that the above calculation formula is formed by only square calculation of an input variable and is advantageous for computer data processing. According to Formula (59), a calculation formula of moving average processing is proposed.

$$\begin{matrix}[ Math . 65 ] & \\ {V}_{gd} ( t ) = \frac{1}{M} {\sum }_{k = 0}^{M - 1} \sqrt{\begin{matrix}\frac{{\{ Re [ {v}_{2} ( t - {kT}_{1} ) ] \}}^{2} + {\{ Re [ {v}_{2} ( t - 2 T - {kT}_{1} ) ] \}}^{2}}{2} - \\ {\{ Re [ {v}_{2} ( t - T - {kT}_{1} ) ] \}}^{2} ( 2 {f}_{c}^{2} - 1 )\end{matrix}} & ( 65 )\end{matrix}$$

(Another Calculation Formula (a Second Calculation Formula) Concerning the Alternating-Current Voltage Amplitude)

The inventor of the present application has also attempted derivation of another calculation formula concerning the alternating-current voltage amplitude. Specifically, the inventor of the present application has found out the following formula and the formula following the following formula representing an addition and a subtraction of members in the gauge differential voltage group, substituted the related product of the real number multiplication table in the respective formulas, and performed formula transformation:

$$\begin{matrix}[ Math . 66 ] & \\ \begin{matrix}{v}_{21} + {v}_{23} + 2 {v}_{22} = - 2 V sin \frac{α}{2} [ \begin{matrix}sin ( ω t + α ) + sin ( ω t - α ) + \\ 2 sin ( ω t )\end{matrix} ] \\ = - 4 V sin \frac{α}{2} ( cos α + 1 ) sin ( ω t ) \\ = - 8 V sin \frac{α}{2} {cos}^{2} \frac{α}{2} sin ( ω t )\end{matrix} & ( 66 ) \\ [ Math . 67 ] & \\ \begin{matrix}{v}_{21} - {v}_{23} = - 2 V sin \frac{α}{2} [ sin ( ω t + α ) - sin ( ω t - α ) ] \\ = - 4 V sin \frac{α}{2} sin α cos ( ω t )\end{matrix} & ( 67 )\end{matrix}$$

According to the two formulas, a calculation formula of the alternating-current voltage amplitude is obtained as indicated by the following formula:

$$\begin{matrix}[ Math . 68 ] & \\ \begin{matrix}V = \sqrt{\begin{matrix}{( \frac{{v}_{21} + {v}_{23} + 2 {v}_{22}}{8 sin \frac{α}{2} {cos}^{2} \frac{α}{2}} )}^{2} + \\ {( \frac{{v}_{21} - {v}_{23}}{4 sin \frac{α}{2} sin α} )}^{2}\end{matrix}} \\ = \frac{\sqrt{2}}{4 \sqrt{1 - {f}_{c}^{2}}} \\ \sqrt{\frac{{( {v}_{21} + {v}_{23} + 2 {v}_{22} )}^{2}}{1 + {f}_{c}} + \frac{{( {v}_{21} - {v}_{23} )}^{2}}{1 - {f}_{c}}}\end{matrix} & ( 68 )\end{matrix}$$

A calculation formula for the moving average processing can be represented by the following formula:

$$\begin{matrix}[ Math . 69 ] & \\ V ( t ) = \frac{\sqrt{2}}{4 M \sqrt{1 - {f}_{c}^{2}}} {\sum }_{k = 0}^{M - 1} \sqrt{\frac{{\{ {v}_{2 add} ( t , k ) \}}^{2}}{1 + {f}_{c}} + \frac{{\{ {v}_{2 sub} ( t , k ) \}}^{2}}{1 - {f}_{c}}} & ( 69 )\end{matrix}$$

Note that a calculation formula of v_{2add}(t,k) and V_{2sub}(k) in a square root sign of the above formula is as indicated by the following formula:

$$\begin{matrix}[ Math . 70 ] & \\ \{ \begin{matrix}{v}_{2 add} ( t , k ) = Re [ {v}_{2} ( t - {kT}_{1} ) ] + Re [ {v}_{2} ( t - 2 T - {kT}_{1} ) ] + \\ 2 Re [ {v}_{2} ( t - T - {kT}_{1} ) ] \\ {v}_{2 sub} ( t , k ) = Re [ {v}_{2} ( t - {kT}_{1} ) ] - Re [ {v}_{2} ( t - 2 T - {kT}_{1} ) ]\end{matrix} & ( 70 )\end{matrix}$$

A root mean square value of an alternating-current voltage can be calculated using the following formula:

$$\begin{matrix}[ Math . 71 ] & \\ {V}_{rms} = \frac{V}{\sqrt{2}} = \frac{1}{4 \sqrt{1 - {f}_{c}^{2}}} \sqrt{\frac{{( {v}_{21} + {v}_{23} + 2 {v}_{22} )}^{2}}{1 + {f}_{c}} + \frac{{( {v}_{21} - {v}_{23} )}^{2}}{1 - {f}_{c}}} & ( 71 )\end{matrix}$$

As explained above, various invariants have been found according to the multiplication table of the gauge differential voltage group and the arithmetic operation (the addition, the subtraction, etc.) for the gauge differential voltage group.

(A Characteristic Triangle by a Gauge Voltage and a Gauge Differential Voltage)

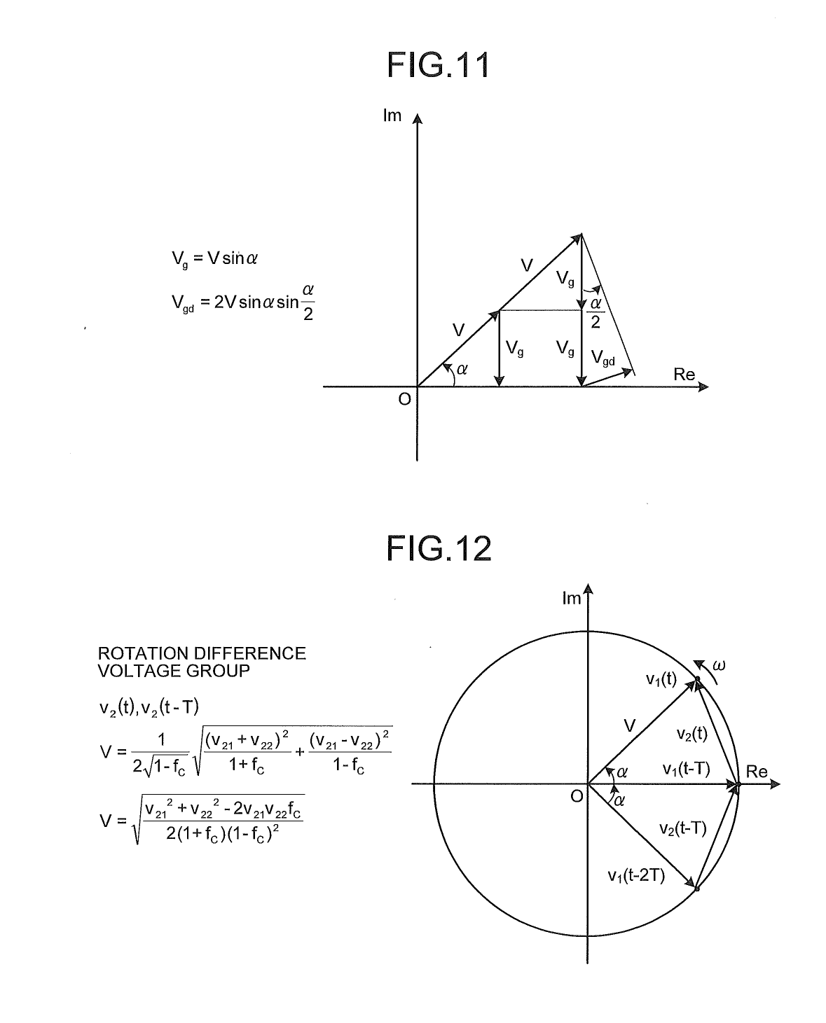

FIG. 11 is a diagram of a characteristic triangle by a gauge voltage and a gauge differential voltage. A gauge voltage V_{g} and a gauge differential voltage V_{gd} are shown in a relation with the alternating-current voltage amplitude V and the rotation phase angle α. The gauge voltage V_{g} is a product of a sine value of the rotation phase angle α and the alternating-current voltage amplitude V. The gauge differential voltage V_{gd} is a double value of a product of a sine value of a half of the rotation phase angle α and the gauge voltage V_{g}. Therefore, the gauge voltage V_{g} and the gauge differential voltage V_{gd} can be represented by the relation shown in the figure. It is seen from such a figure that the gauge voltage V_{g} and the gauge differential voltage V_{gd} are generated according to the rotation phase angle α and are invariants.

In the following explanation, a symmetric differential voltage group that can be calculated and output at higher speed by reducing the number of rotation differential vectors, which are constituent members of the gauge differential voltage group, by one is proposed. Note that the symmetric differential voltage group, that is, the symmetric differential voltage group consisting of two rotation differential vectors obtained by reducing the number of rotation differential vectors by one is referred to as rotation differential voltage group.

(A Rotation Differential Voltage Group on a Complex Plane)

FIG. 12 is a diagram of a rotation differential voltage group on a complex plane. Two differential voltage rotation vectors on the complex plane shown in FIG. 12 can be represented by the following formula:

$$\begin{matrix}[ Math . 72 ] & \\ \{ \begin{matrix}{v}_{2} ( t ) = V {e}^{j ( ω t + α )} - V {e}^{j ( ω t )} \\ {v}_{2} ( t - T ) = V {e}^{j ( ω t )} - V {e}^{j ( ω t - α )}\end{matrix} & ( 72 )\end{matrix}$$

In the above formula, V represents an alternating-current voltage amplitude, ω represents rotation angular velocity, T represents the gauge sampling cycle, and α represents a rotation phase angle at T. In FIG. 12, two differential voltage rotation vectors v₂(t) and v₂(t−T) have symmetry. Even at another time or even if the two differential voltage rotation vectors are present in other places, the rotation phase angle α between the two differential voltage rotation vectors does not change. That is, the rotation differential voltage group is also a structure having a characteristic of rotation invariance like the gauge differential voltage group explained above.

(A Vector Multiplication Table of the Rotation Differential Voltage Group)

To check an invariant of the rotation differential voltage group, a vector multiplication table of the rotation differential voltage group shown in Table 7 below is established.

TABLE 7
A vector group table of the rotation differential voltage group

| x | v₂(t) | v₂(t − T) |
|---|---|---|
| v₂(t) | v₂²(t) | v₂(t − T)v₁(t) |
| v₂(t − T) | v₂(t)v₂(t − T) | v₂²(t − T) |

Differential voltage rotation vectors shown in the vector multiplication table are complex number state variables. An “×” sign in the table means that multiplication of an element on a table side and an element at a table top is performed. In this case, product elements of the vector multiplication table of the rotation differential voltage group can be represented as indicated by the following formula:

$$\begin{matrix}[ Math . 73 ] & \\ \{ \begin{matrix}{v}_{2}^{2} ( t ) = {V}^{2} [ {e}^{j ( 2 ω t + 2 α )} + {e}^{j ( 2 ω t )} - 2 {e}^{j ( 2 ω t + α )} ] \\ {v}_{2} ( t ) {v}_{2} ( t - T ) = {V}^{2} [ {e}^{j ( 2 ω t + α )} + {e}^{j ( 2 ω t - α )} - 2 {e}^{j ( 2 ω t )} ] \\ {v}_{2}^{2} ( t - T ) = {V}^{2} [ {e}^{j ( 2 ω t )} + {e}^{j ( 2 ω t - 2 α )} - 2 {e}^{j ( 2 ω t - α )} ]\end{matrix} & ( 73 )\end{matrix}$$

If calculation of the right side of the above formula is advanced, the formula can be simplified as indicated by the following formula:

$$\begin{matrix}[ Math . 74 ] & \\ \{ \begin{matrix}{v}_{2}^{2} ( t ) = 4 {V}^{2} {sin}^{2} \frac{α}{2} {e}^{j ( 2 ω t + α - π )} \\ {v}_{2} ( t ) {v}_{2} ( t - T ) = 4 {V}^{2} {sin}^{2} \frac{α}{2} {e}^{j ( 2 ω t - π )} \\ {v}_{2}^{2} ( t - T ) = 4 {V}^{2} {sin}^{2} \frac{α}{2} {e}^{j ( 2 ω t - α - π )}\end{matrix} & ( 74 )\end{matrix}$$

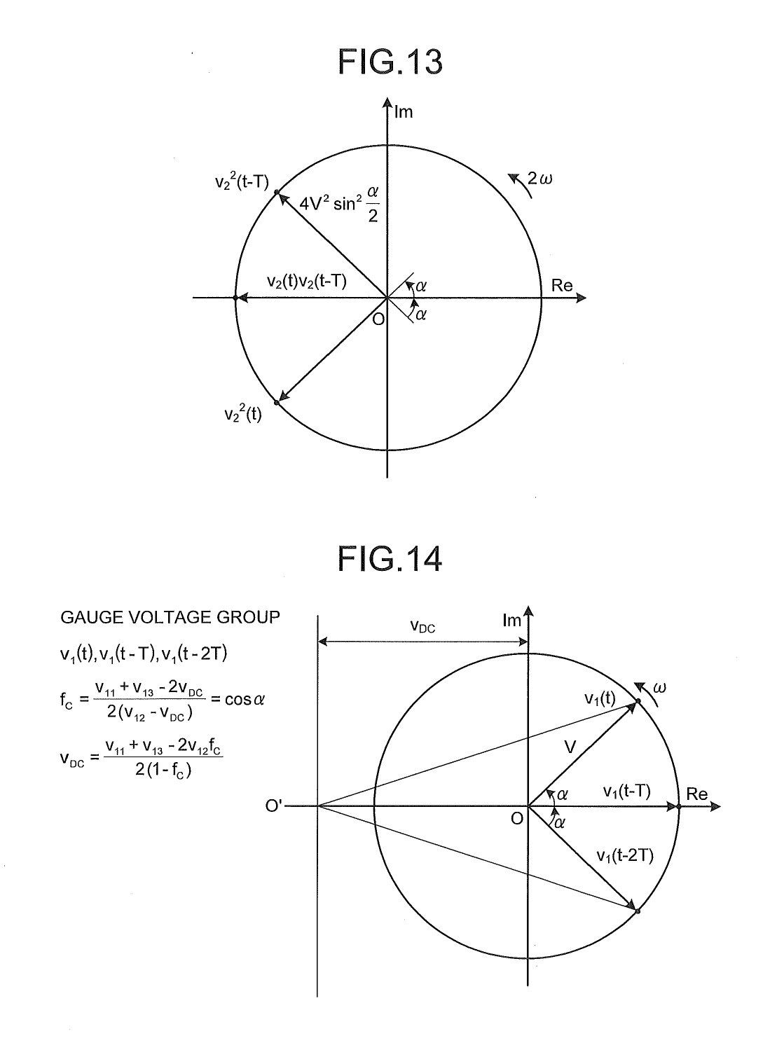

A figure in which vector product elements based on the above formula are represented on a complex plane is FIG. 13. A space generated by product calculation of two vectors is referred to as vector product space. Symmetry intrinsic in an alternating-current sine wave can be seen using the vector product space. In the vector product space, vector product elements rotate counterclockwise at angular velocity of 2ω.

Note that, as shown in FIG. 13, a set of v₂²(t) and v₂²(t−T) has a phase difference α with respect to an intermediate axis (in the example shown in FIG. 13, the real axis (Re axis)). As explained in detail below, a voltage amplitude can be calculated by this set.

(A Real Number Multiplication Table of the Rotation Differential Voltage Group)

To derive a calculation formula of an invariant of the rotation differential voltage group, a real number multiplication table of the rotation differential voltage group shown in Table 8 below is established. Note that, as explained above, as a voltage instantaneous value in the real number multiplication table, a real number part of a differential voltage rotation vector can be used or an imaginary number part of the voltage rotation vector can be used.

TABLE 8
A real number group table of the rotation differential voltage group

| x | v₂₁ | v₂₂ |
|---|---|---|
| v₂₁ | v²₂₁ | v₂₂v₂₁ |
| v₂₂ | v₂₁v₂₂ | v²₂₂ |

The real number multiplication table of the rotation differential voltage group is explained. First, instantaneous value elements, which are constituent elements of the set shown in Table 8, can be represented by the following formula:

$$\begin{matrix}[ Math . 75 ] & \\ \{ \begin{matrix}{v}_{21} = Re [ {v}_{2} ( t ) ] = V [ cos ( ω t + α ) - cos ( ω t ) ] = - 2 V sin \frac{α}{2} sin ( ω t + \frac{α}{2} ) \\ {v}_{22} = Re [ {v}_{2} ( t - T ) ] = V [ cos ( ω t ) - cos ( ω t - α ) ] == - 2 V sin \frac{α}{2} sin ( ω t - \frac{α}{2} )\end{matrix} & ( 75 )\end{matrix}$$

According to the above formula, the product elements shown in Table 8 can be represented as indicated by the following formula:

$$\begin{matrix}[ Math . 76 ] & \\ \{ \begin{matrix}{v}_{21}^{2} = 4 {V}^{2} {sin}^{2} \frac{α}{2} {sin}^{2} ( ω t + \frac{α}{2} ) \\ {v}_{22} {v}_{21} = 4 {V}^{2} {sin}^{2} \frac{α}{2} sin ( ω t + \frac{α}{2} ) sin ( ω t - \frac{α}{2} ) \\ {v}_{22}^{2} = 4 {V}^{2} {sin}^{2} \frac{α}{2} {sin}^{2} ( ω t - \frac{α}{2} )\end{matrix} & ( 76 )\end{matrix}$$

A calculation formula of various invariants related to the rotation differential voltage group is explained using the product elements of the real number multiplication table of the rotation differential voltage group.

(A Calculation Formula (a First Calculation Formula) of an Alternating-Current Voltage Amplitude by the Rotation Differential Voltage Group)

As in the case of the gauge differential voltage group, formula transformation is performed by calculation representing an addition and a subtraction of members.

$$\begin{matrix}[ Math . 77 ] & \\ \{ \begin{matrix}{v}_{21} + {v}_{22} = - 2 V sin α sin ( ω t ) \\ {v}_{21} - {v}_{22} = - 4 V {sin}^{2} \frac{α}{2} cos ( ω t )\end{matrix} & ( 77 )\end{matrix}$$

According to these two formulas, a calculation formula of an alternating-current voltage amplitude is obtained as indicated by the following formula:

$$\begin{matrix}[ Math . 78 ] & \\ V = \sqrt{\frac{{( {v}_{21} + {v}_{22} )}^{2}}{4 {sin}^{2} α} + \frac{{( {v}_{21} - {v}_{22} )}^{2}}{16 {sin}^{4} \frac{α}{2}}} = \frac{1}{2 \sqrt{1 - {f}_{c}}} \sqrt{\frac{{( {v}_{21} + {v}_{22} )}^{2}}{1 + {f}_{c}} + \frac{{( {v}_{21} - {v}_{22} )}^{2}}{1 - {f}_{c}}} & ( 78 )\end{matrix}$$

A calculation formula for moving average processing can be represented by the following formula:

$$\begin{matrix}[ Math . 79 ] & \\ V ( t ) = \frac{1}{2 M \sqrt{1 - {f}_{c}}} {\sum }_{k = 0}^{M - 1} \sqrt{\frac{{\{ {V}_{2 add} ( t , k ) \}}^{2}}{1 + {f}_{c}} + \frac{{\{ {V}_{2 sub} ( t , k ) \}}^{2}}{1 - {f}_{c}}} & ( 79 )\end{matrix}$$

Note that a calculation formula of v_{2add}(t,k) and v_{2sub} (t k) in a square root sign of the above formula is as indicated by the following formula:

$$\begin{matrix}[ Math . 80 ] & \\ \{ \begin{matrix}{v}_{2 add} ( t , k ) = Re [ {v}_{2} ( t - {kT}_{1} ) ] + Re [ {v}_{2} ( t - T - {kT}_{1} ) ] \\ {v}_{2 sub} ( t , k ) = Re [ {v}_{2} ( t - {kT}_{1} ) ] - Re [ {v}_{2} ( t - T - {kT}_{1} ) ]\end{matrix} & ( 80 )\end{matrix}$$

### (A Calculation Formula (a Second Calculation Formula) of an Alternating-Current Voltage Amplitude by the Rotation Differential Voltage Group)

The inventor of the present application has found out the following formula for calculating an alternating-current voltage amplitude, substituted the related product of the real number multiplication table in the formula, and performed formula transformation.

$$\begin{matrix}[ Math . 81 ] & \\ {v}_{21}^{2} + {v}_{22}^{2} - 2 {v}_{22} {v}_{21} cos α = 4 {V}^{2} {sin}^{2} α {sin}^{2} \frac{α}{2} & ( 81 )\end{matrix}$$

According to the above formula, a calculation formula of an alternating-current voltage amplitude is obtained as indicated by the following formula:

$$\begin{matrix}[ Math . 82 ] & \\ V = \sqrt{\frac{{v}_{21}^{2} + {v}_{22}^{2} - 2 {v}_{22} {v}_{21} cos α}{4 {sin}^{2} α {sin}^{2} \frac{α}{2}}} = \sqrt{\frac{{v}_{21}^{2} + {v}_{22}^{2} - 2 {v}_{22} {v}_{21} {f}_{c}}{2 ( 1 + {f}_{c} ) {( 1 - {f}_{c} )}^{2}}} & ( 82 )\end{matrix}$$

Similarly, a calculation formula for moving average processing can be represented by the following formula:

$$\begin{matrix}[ Math . 83 ] & \\ V ( t ) = \frac{1}{M} {\sum }_{k = 0}^{M - 1} \sqrt{\frac{{v}_{2 add 2} ( t , k )}{2 ( 1 + {f}_{c} ) {( 1 - {f}_{c} )}^{2}}} & ( 83 )\end{matrix}$$

Note that a calculation formula of v_{2add2}(t,k) in a square root sign of the above formula is as indicated by the following formula:

[Math. 84]

v_{2add2}(t,k)={Re[v₂(t−kT₁)]}²+{Re[v₂(t−T−kT₁)]}−2f_{c}×{Re[v₂(t−kT₁)]}×{Re[v₂(t−T−kT₁)]} (84)

(A Symmetry Index of the Rotation Differential Voltage Group)

The following formula is proposed as a symmetry index of the rotation differential voltage group.

$$\begin{matrix}[ Math . 85 ] & \\ \vert \frac{{V}_{1} - {V}_{2}}{{V}_{1}} \vert > {dV}_{SET} & ( 85 )\end{matrix}$$

In the above formula, V₁ represents a calculation result by the first calculation formula of an alternating-current voltage amplitude, V₂ represents a calculation result by the second calculation formula of an alternating-current voltage amplitude, and dV_{SET} represents a setting value. When the above formula is satisfied, symmetry of the rotation differential voltage group is broken. Therefore, at a point in time when the symmetry is broken, a calculation value before the break of the symmetry is latched. On the other hand, when the above formula is not satisfied, it is determined that the symmetry is not broken, and a calculation value of the present symmetric group is used.

(Calculation of a Direct-Current Electric Quantity)

In a prior invention by the inventor of the present application (e.g., Patent Literature 3), a calculation formula of a direct-current offset voltage is derived. On the other hand, the measuring method according to the present invention can also be applied to measurement of various direct-current electric quantities such as a direct-current offset voltage. A pure direct-current component does not exist in the world, and a combination of various frequency components is considered to be a direct current. Therefore, in the present invention, first, a fundamental wave frequency component is measured (in the embodiment of the present invention, a nominal frequency of the power system, however, different fundamental waves are present depending on various circuits). Thereafter, a fundamental wave component is cut using a gauge voltage group (a gauge current group) to calculate a direct-current component. Further, moving average processing for attaining a noise reduction is performed.

(A Calculation Formula (a First Calculation Formula) of a Direct-Current Voltage by the Gauge Voltage Group)

FIG. 14 is a diagram of a gauge voltage group on a complex plane including a direct-current component. Real number part instantaneous values of a gauge voltage group v₁(t), v₁(t−T), and v₁(t−2T) shown in FIG. 14 can be respectively represented by the following formulas:

$$\begin{matrix}[ Math . 86 ] & \\ \{ \begin{matrix}{v}_{11} = V cos ( ω t + α ) + {v}_{D C} \\ {v}_{12} = V cos ( ω t ) + {v}_{D C} \\ {v}_{13} = V cos ( ω t - α ) + {v}_{D C}\end{matrix} & ( 86 )\end{matrix}$$

Components obtained by subtracting a direct-current component v_{DC} from the real number instantaneous values of the gauge voltage group satisfy Formula (11) for deriving the frequency coefficient of the gauge voltage group. Therefore, the following formula holds:

$$\begin{matrix}[ Math . 87 ] & \\ {f}_{c} = \frac{{v}_{11} + {v}_{13} - 2 {v}_{D C}}{2 ( {v}_{12} - {v}_{D C} )} = \frac{V cos ( ω t + α ) + V cos ( ω t - α )}{2 V cos ( ω t )} = cos α & ( 87 )\end{matrix}$$

According to the above formula, a direct-current voltage can be calculated using the following formula:

$$\begin{matrix}[ Math . 88 ] & \\ {v}_{D C} = \frac{{v}_{11} + {v}_{13} - 2 {v}_{12} {f}_{C}}{2 ( 1 - {f}_{C} )} & ( 88 )\end{matrix}$$

(A Moving Average of the Direct-Current Voltage)

When the direct-current voltage is calculated, to reduce the influence of noise, as in calculating other electric quantities, it is effective to perform moving average processing indicated by the following formula:

$$\begin{matrix}[ Math . 89 ] & \\ {v}_{D C} = \frac{1}{M} {\sum }_{k = 0}^{M - 1} \frac{\begin{matrix}Re [ {v}_{1} ( t - {kT}_{1} ) ] + \\ Re [ {v}_{1} ( t - 2 T - {kT}_{1} ) ] - \\ 2 Re [ {v}_{1} ( t - T - {kT}_{1} ) ] {f}_{C}\end{matrix}}{2 ( 1 - {f}_{C} )} & ( 89 )\end{matrix}$$

(A Calculation Formula (a Second Calculation Formula) of Another Direct-Current Voltage by the Gauge Voltage Group)

A component obtained by subtracting the direct-current component v_{DC} from the real number instantaneous values of the gauge voltage group has symmetry. Therefore, the component satisfies the following formula:

[Math. 90]

V_{g}²=(v₁−v_{DC})²−(v₁₁−v_{DC})(v₁₃−v_{DC}) (90)

According to this formula and Formula (20), the following formula is obtained:

[Math. 91]

V_{g}²=(v₁₂−v_{DC})²−(v₁₁−v_{DC})(v₁₃−v_{DC})=V² sin²α (91)

If the above formula is developed, the direct-current voltage v_{DC} can be calculated using the following formula:

$$\begin{matrix}[ Math . 92 ] & \\ {v}_{D C} = \frac{{V}^{2} {sin}^{2} α - {v}_{12}^{2} + {v}_{11} {v}_{13}}{{v}_{11} + {v}_{13} - 2 {v}_{12}} & ( 92 )\end{matrix}$$

According to the calculation formula (e.g., Formula (60)) of the alternating-current voltage amplitude by the gauge differential voltage, the following formula holds:

$$\begin{matrix}[ Math . 93 ] & \\ {V}^{2} {sin}^{2} α = {( \frac{\sqrt{2} {V}_{gd}}{2 ( 1 - {f}_{C} ) \sqrt{1 + {f}_{C}}} )}^{2} ( 1 - {f}_{C}^{2} ) = \frac{{V}_{gd}^{2}}{2 ( 1 - {f}_{C} )} & ( 93 )\end{matrix}$$

According to Formula (93), Formula (92) can be transformed as indicated by the following formula:

$$\begin{matrix}[ Math . 94 ] & \\ {v}_{D C} = \frac{\frac{{V}_{gd}^{2}}{2 ( 1 - {f}_{C} )} - {v}_{12}^{2} + {v}_{11} {v}_{13}}{{v}_{11} + {v}_{13} - 2 {v}_{12}} & ( 94 )\end{matrix}$$

Note that, when the direct-current voltage based on Formula (94) is calculated, to reduce the influence of noise, as in calculating other electric quantities, it is effective to perform moving average processing indicated by the following formula:

$$\begin{matrix}[ Math . 95 ] & \\ {v}_{D C} = \frac{1}{M} {\sum }_{k = 0}^{M - 1} \frac{\frac{{V}_{gd}^{2}}{2 ( 1 - {f}_{C} )} - \begin{matrix}{\{ Re [ v ( t - T - {kT}_{1} ) ] \}}^{2} + \\ Re [ v ( t - {kT}_{1} ) ] Re [ v ( t - 2 T - {kT}_{1} ) ]\end{matrix}}{\begin{matrix}Re [ v ( t - {kT}_{1} ) ] + \\ Re [ v ( t - 2 T - {kT}_{1} ) ] - \\ 2 Re [ v ( t - T - {kT}_{1} ) ]\end{matrix}} & ( 95 )\end{matrix}$$

(A Calculation Formula of Direct-Current Power)

A calculation formula of direct-current power in a circuit network in which a direct current and an alternating current are likely to flow together is proposed.

First, the direct-current power can be calculated using the following formula:

[Math. 96-1]

P_{DC}=V_{DC}i_{DC} (96-1)

Note that a direct-current voltage v_{DC} in the above formula can be calculated by the gauge voltage group or the rogation voltage group. A direct current i_{DC} in the above formula can be calculated by a gauge current group (explanation is omitted) forming a structure (a symmetric group) same as the gauge voltage group.

The following calculation formula of a direct-current power is proposed:

[Math. 96-2]

W_{DC}=P_{DC}×t (96-2)

In the above formula, t represents a measurement time and W_{DC} represents a direct-current power amount.

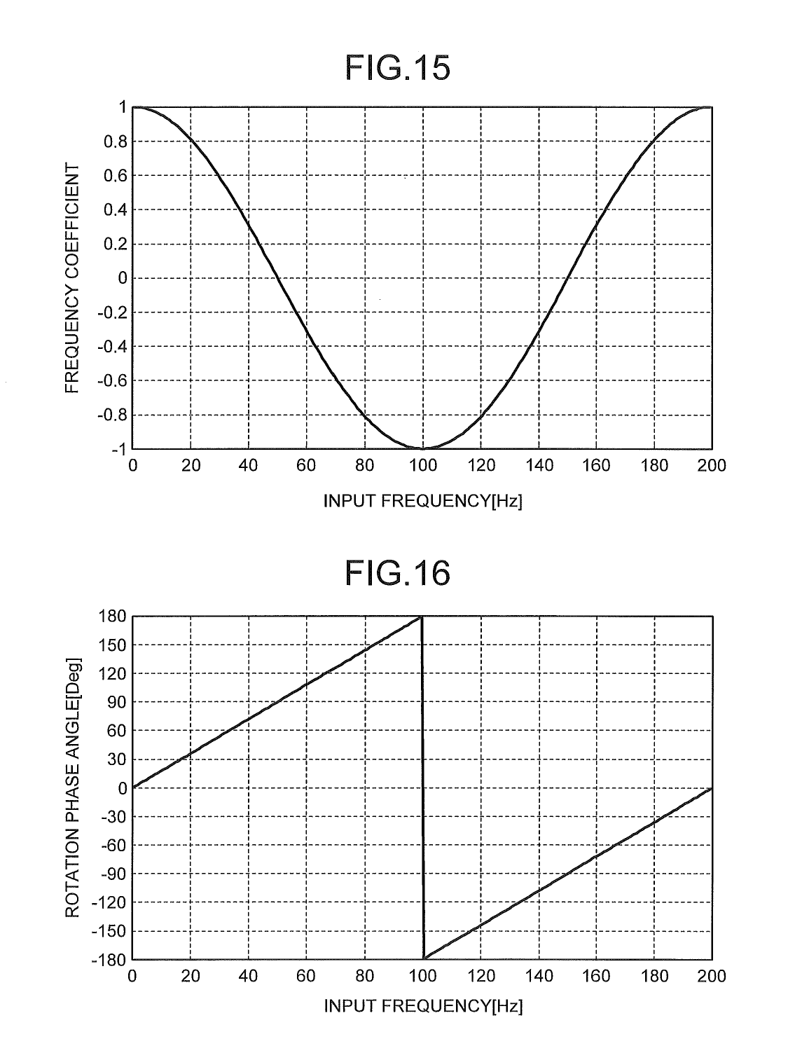

A frequency characteristic and a frequency gain characteristic related to the measuring method of this application are examined on the basis of simulation results shown in FIG. 15 to FIG. 18. Note that simulation conditions are as described below.

Gauge sampling frequency: 200 hertz

Input waveform: sine wave

Frequency of the input waveform: variable from 0 to 200 hertz

Alternating-current voltage amplitude: 1 volt

Alternating-current voltage initial phase angle: 30 degrees

FIG. 15 is a frequency characteristic chart of a frequency coefficient at the gauge sampling frequency of 200 hertz. As shown in FIG. 15, the frequency coefficient is a cosine function. One frequency component corresponds to two input frequencies. One input frequency (a low-frequency side) is equal to or smaller than a half of the gauge sampling frequency. The other input frequency (a high-frequency side) is equal to or larger than a half of the gauge sampling frequency. It is seen that the two input frequencies have symmetry with a half of the gauge sampling frequency set as an axis.

FIG. 16 is a frequency characteristic chart of a rotation phase angle at the gauge sampling frequency of 200 hertz. In FIG. 16, when an input frequency is equal to or lower than a half of the gauge sampling frequency, as in the prior invention (Patent Literature 3), the rotation phase angle is present in a range of zero to 180 degrees. On the other hand, when the input frequency is equal to or higher than a half of the gauge sampling frequency, unlike the prior invention, the rotation phase angle is present in a range of minus 180 degrees to zero. That is, because the rotation phase angle that takes a negative value is defined, in the present invention, the input frequency and the rotation phase angle are in a relation of a single-valued function. Excluding a half of the gauge sampling frequency, the input frequency can also be unequivocally determined if the rotation phase angle is known.

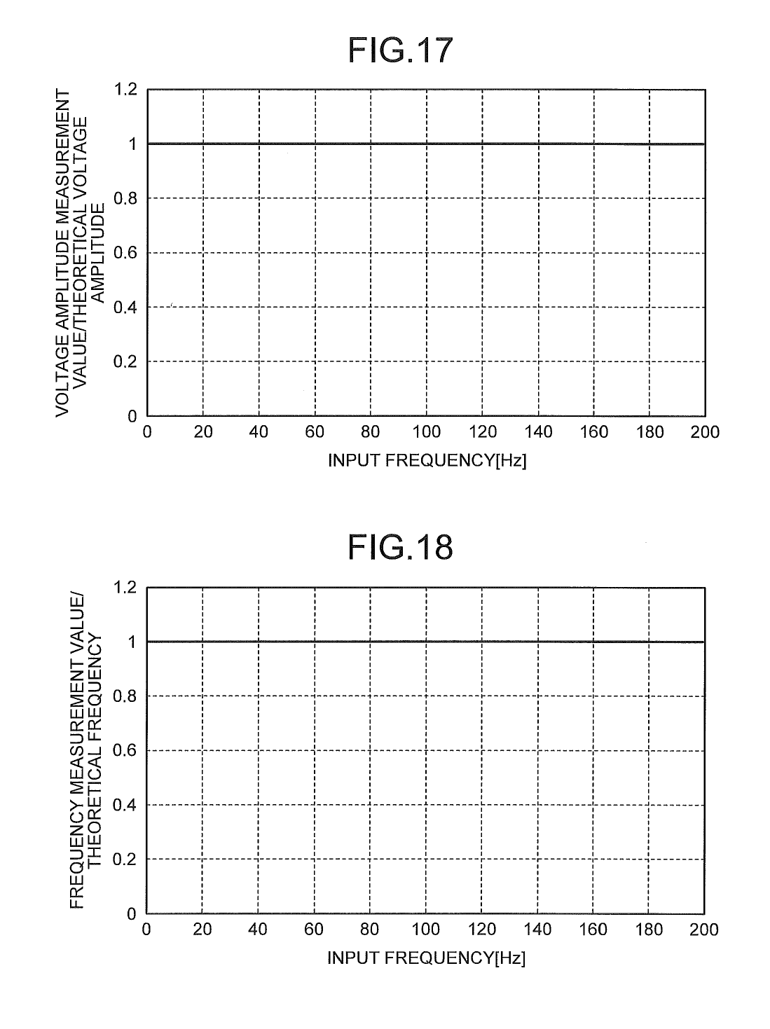

FIG. 17 is a frequency gain characteristic chart of a voltage amplitude measurement value at the gauge sampling frequency 200 hertz. In the prior invention, a region where a frequency gain is “1” is a half (in an example shown in FIG. 17, 100 hertz) of the gauge sampling frequency. However, in the present invention, it can be observed that it is made possible to expand the region of the frequency gain=1 to the gauge sampling frequency of 200 Hz.

FIG. 18 is a frequency gain characteristic chart of a frequency measurement value at the gauge sampling frequency 200 hertz. As shown in FIG. 18, the frequency gain of the frequency measurement value is “1” in the entire gauge sampling frequency range. It is seen that the region of the frequency gain=1 can be expanded to the gauge sampling frequency of 200 hertz.

The various calculation formulas presented above are applicable to various electric-quantity measuring apparatuses. Two embodiments are presented below as application examples of the electric-quantity measuring apparatuses. One is a real-time frequency measuring apparatus. The other is a voltage measuring apparatus. Note that it goes without saying that the present invention is not limited to the embodiments.

### First Embodiment

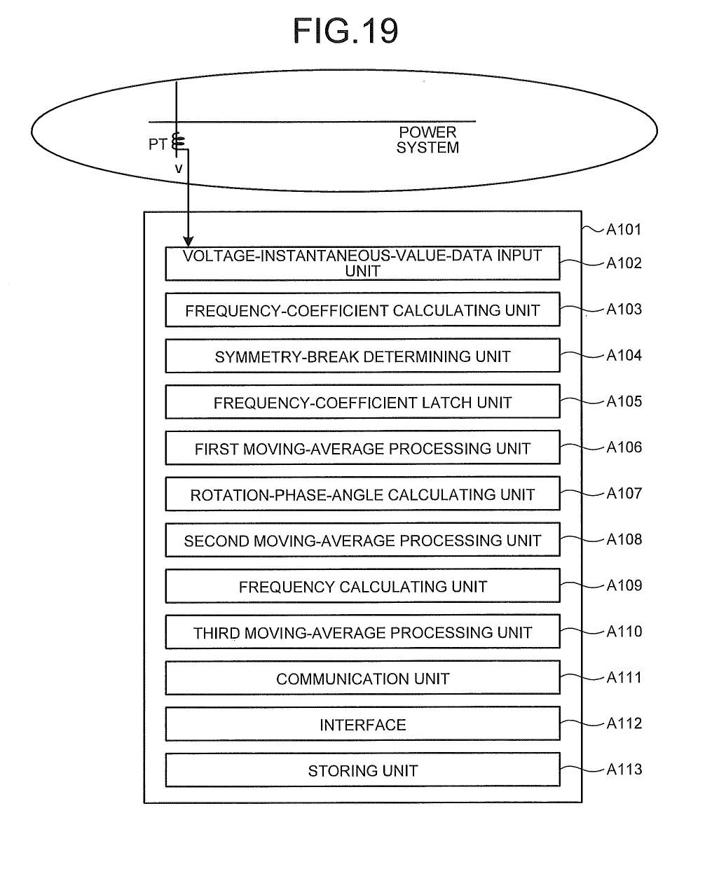

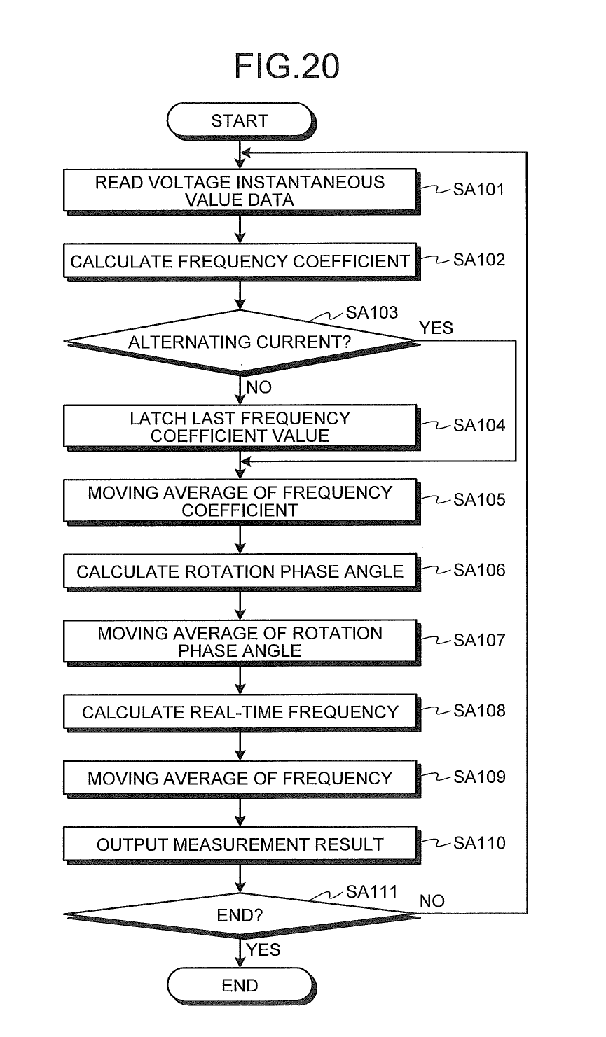

FIG. 19 is a diagram showing a functional configuration of a real-time frequency measuring apparatus according to a first embodiment. FIG. 20 is a flowchart for explaining a flow of processing in the real-time frequency measuring apparatus.

As shown in FIG. 19, a real-time-frequency measuring apparatus A101 according to the first embodiment includes a voltage-instantaneous-value-data input unit A102, a frequency-coefficient calculating unit A103, a symmetry-break determining unit A104, a frequency-coefficient latch unit A105, a first moving-average processing unit A106, a rotation-phase-angle calculating unit A107, a second moving-average processing unit A108, a frequency calculating unit A109, a third moving-average processing unit A110, a communication unit A111, an interface A112, and a storing unit A113. The communication unit A111 performs communication processing in performing communication with other apparatuses. The interface A112 performs processing in outputting a calculation result and the like to a display device and an external device. The storing unit A113 performs processing for storing measurement data, a calculation result, and the like.

(Step SA101)

In the configuration explained above, the voltage-instantaneous-value-data input unit A102 performs processing for reading out a voltage instantaneous value from a potential transformer (PT) provided in a power system. Note that data of the read-out voltage instantaneous value is stored in the storing unit A113.

(Step SA102)

The frequency-coefficient calculating unit A103 calculates a frequency coefficient using the reproduced following formula on the basis of, for example, the calculation processing in which the gauge differential voltage group is used.

$$\begin{matrix}[ Math . 97 ] & \\ {f}_{C} = \frac{{v}_{21} + {v}_{23}}{2 {v}_{22}} & ( 97 )\end{matrix}$$

The calculation processing of the frequency coefficient can be explained as follows when the calculation processing is collectively explained according to the concept of the calculation processing explained above. That is, the frequency-coefficient calculating unit A103 performs processing for calculating, as a frequency coefficient (f_{c}), a value ((v₂₁+v₂₃)/(2v₂₂)) obtained by normalizing, with a differential voltage instantaneous value (v₂₂) at intermediate time, an average ((v₂₁+v₂₂)/2) of a sum (v₂₁+v₂₂) of differential voltage instantaneous values other than the intermediate time among differential voltage instantaneous value data (v₂₁, v₂₂, v₂₃) at three points representing an inter-distal end distance between voltage instantaneous value data at adjacent two points in voltage instantaneous value data at continuous at least four points extracted, out of voltage instantaneous value data obtained by sampling a measurement target alternating-current voltage at a predetermined data collection sampling frequency, at a gauge sampling frequency lower than a data collection sampling frequency and equal to or higher than a frequency of the alternating-current voltage.

(Step SA103)

The symmetry-break determining unit A104 determines a break of symmetry using a determination formula (the reproduced following formula) of the symmetry index of the gauge differential voltage group:

$$\begin{matrix}[ Math . 98 ] & \\ \vert {f}_{c} \vert = \vert \frac{{v}_{21} + {v}_{23}}{2 {v}_{22}} \vert > 1 & ( 98 )\end{matrix}$$

(Step SA104)

When the above formula holds (No at step SA103), the symmetry-break determining unit A104 determines that symmetry is broken. The symmetry-break determining unit A104 latches and uses the last frequency coefficient value using, for example, the following formula:

[Math. 99]

f_{c}(t)=f_{c}(t−T₁) (99)

On the other hand, when Formula (98) does not hold (Yes at step SA103), the symmetry-break determining unit A104 determines that symmetry is not broken and shifts to step SA105 without latching the frequency coefficient value.

(Step SA105)

The first moving-average processing unit A106 performs moving average processing for a frequency coefficient using the reproduced following formula:

$$\begin{matrix}[ Math . 100 ] & \\ {f}_{c} ( t ) = \frac{1}{M} {\sum }_{k = 0}^{M - 1} {f}_{c} ( t - {kT}_{1} ) & ( 100 )\end{matrix}$$

(Step SA106) The rotation-phase-angle calculating unit A107 calculates a rotation phase angle using the reproduced following formula:

$$\begin{matrix}[ Math . 101 ] & \\ α = \{ \begin{matrix}{cos}^{- 1} {f}_{c} & for f \leq {f}_{s} / 2 , \\ - {cos}^{- 1} {f}_{c} & for {f}_{s} / 2 < f < {f}_{s} .\end{matrix} & ( 101 )\end{matrix}$$

(Step SA107)

The second moving-average processing unit A108 performs moving average processing concerning the rotation phase angle using, for example, the following formula:

$$\begin{matrix}[ Math . 102 ] & \\ α ( t ) = \frac{1}{M} {\sum }_{k = 0}^{M - 1} α ( t - {kT}_{1} ) & ( 102 )\end{matrix}$$

(Step SA108)

The frequency calculating unit A109 calculates a real-time frequency using the following formula. In the formula, f represents a real-time frequency and fₛ represents a gauge sampling frequency.

$$\begin{matrix}[ Math . 103 ] & \\ f = \{ \begin{matrix}\frac{α}{2 π} {f}_{s} & for α > 0 , \\ ( \frac{α}{2 π} + 1 ) {f}_{s} & for α < 0 , \\ \frac{{f}_{s}}{2} & for α = 0.\end{matrix} & ( 103 )\end{matrix}$$

(Step SA109)

The third moving-average processing unit A110 performs moving average processing concerning a frequency (a real-time frequency) using, for example, the following formula:

$$\begin{matrix}[ Math . 104 ] & \\ f ( t ) = \frac{1}{M} {\sum }_{k = 0}^{M - 1} f ( t - {kT}_{1} ) & ( 104 )\end{matrix}$$

(Step SA110)

The real-time-frequency measuring apparatus A101 outputs a measurement result. Note that the measurement result is used as a frequency relay and a real-time frequency of a power system state monitoring point.

(Step SA111)

The real-time-frequency measuring apparatus A101 determines whether the processing ends. If the processing does not end (No at step SA111), the real-time-frequency measuring apparatus A101 returns to step SA101. On the other hand, if the processing ends (Yes at step SA111), the real-time-frequency measuring apparatus A101 leaves the flow.

Utility and effects of the real-time-frequency measuring apparatus according to the first embodiment are explained on the basis of a simulation result obtained using numerical value examples of cases 1 to 3.

First, parameters of the case 1 are as shown in Table 9 below. Note that, in the case 1, it is assumed that a frequency changes at a fixed rate of change from a point in time of setting.

TABLE 9
Parameters of the case 1

| Item name | Setting value | |
|---|---|---|
| Power system rated frequency | 60 | Hz |
| Data collection sampling | 4000 | Hz |
| frequency f₁ | | |
| Gauge sampling frequency f_{S} | 200 | Hz |
| Real-time frequency f | 59 | Hz |
| Alternating-current voltage | 1 | V |
| amplitude V | | |
| Alternating-current voltage | 0 | Deg |
| initial phase angle | | |
| Frequency fluctuation | Increase at 2.5 Hz/S from | |
| occurrence time t₁ | point in time of 0.05 S | |
| Moving average length T_{avg} | 16.67 | ms |
| Simulation end time T_{end} | 0.4 | S |

A voltage instantaneous value waveform is represented as indicated by the following formula on the basis of Table 9.

$$\begin{matrix} [ Math . 105 ] & \\ v = \{ \begin{matrix}cos ( 2 π f t ) = cos ( 370.71 t ) & for t < 0.05 , \\ \begin{matrix}cos [ 2 π ( f + df \times t ) t + {φ}_{C} ] = \\ cos [ 6.283 ( 59 + 0.000625 t ) t + {φ}_{C} ]\end{matrix} & for t \geq 0.05 .\end{matrix} & ( 105 )\end{matrix}$$

In the above formula, φ_{c} represents a voltage phase angle at a change point in time (t=0.05 s). According to the above table, a ratio (n) of the data collection sampling frequency and the gauge sampling frequency in this simulation is as indicated by the following formula:

$$\begin{matrix}[ Math . 106 ] & \\ n = \frac{4000}{200} = 20 & ( 106 )\end{matrix}$$

In this simulation, the number of data points of the moving average processing is as indicated by the following formula:

$$\begin{matrix}[ Math . 107 ] & \\ M = int ( \frac{{T}_{avg}}{{T}_{1}} ) = int ( \frac{0.01667}{1 / 4000} ) = 66 & ( 107 )\end{matrix}$$

This numerical value is about one cycle of a system nominal frequency.

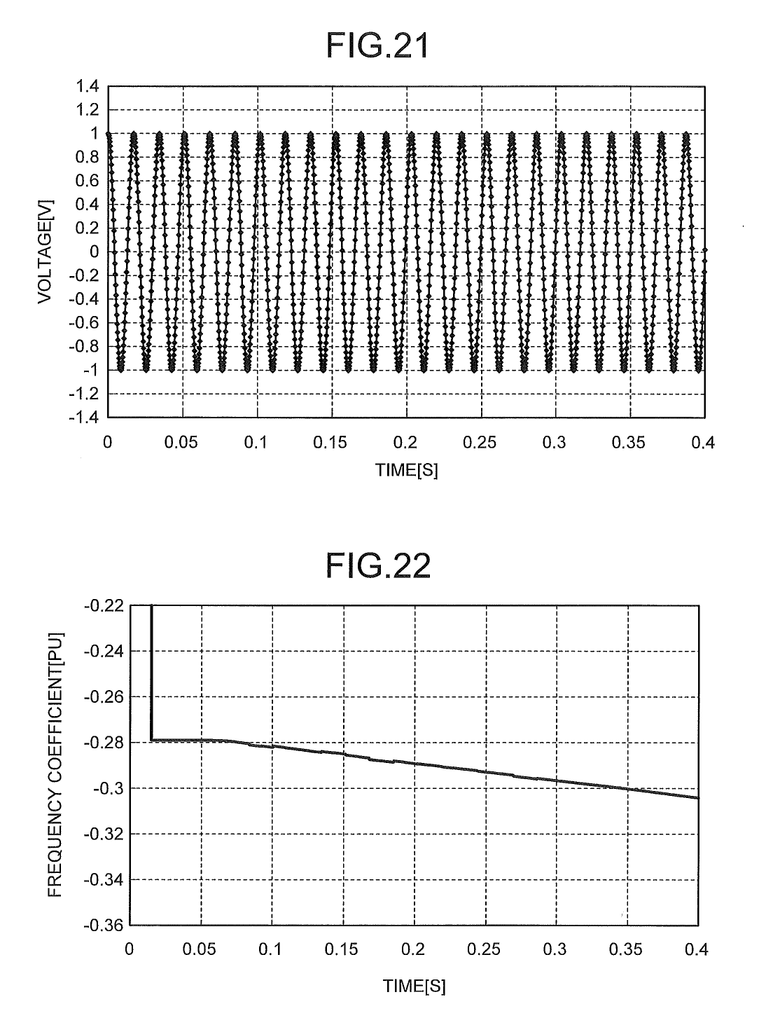

FIG. 21 is a diagram of a voltage instantaneous value waveform in the case 1. It is seen that, in the case 1, a data sampling frequency is set to 4000 hertz and a large number of data are collected.

FIG. 22 is a diagram of a measurement result of a frequency coefficient in the case 1. In FIG. 22, it is seen that the frequency coefficient decreases little by little after 0.05 second. Note that a frequency coefficient before a frequency changes can be calculated as indicated by the following formula:

$$\begin{matrix}[ Math . 108 ] & \\ {f}_{c} = \frac{{v}_{21} + {v}_{23}}{2 {v}_{22}} = - 0.2790 ( PU ) & ( 108 )\end{matrix}$$

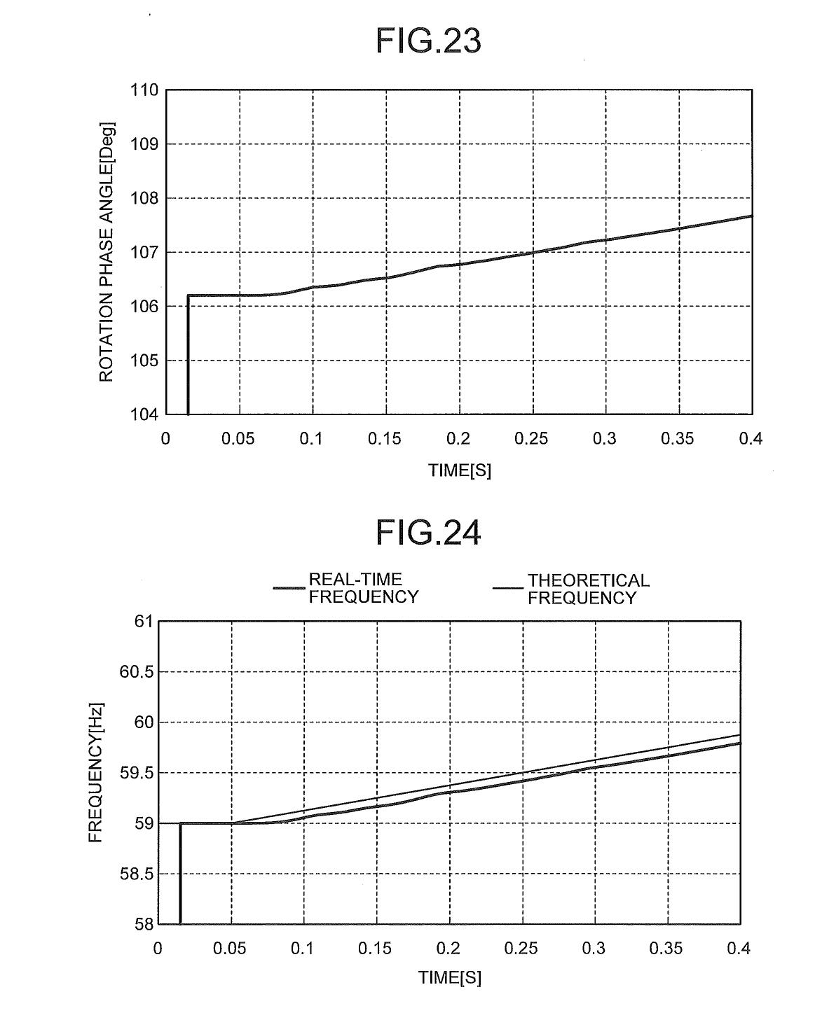

FIG. 23 is a diagram showing a measurement result of a rotation phase angle in the case 1. In FIG. 23, it is seen that the rotation phase angle increases little by little according to the change (the decrease) in the frequency coefficient. Note that the rotation phase angle before the frequency changes can be calculated as indicated by the following formula:

[Math. 109]

α=cos⁻¹f_{c}=cos⁻¹(−0.2790)=106.2(Deg) (109)

FIG. 24 is a diagram showing a measurement result of a real-time frequency in the case 1. In FIG. 24, it is seen that the real-time frequency increases little by little according to the change (the increase) in the rotation phase angle. Note that the real-time frequency before the frequency changes can be calculated as indicated by the following formula:

$$\begin{matrix}[ Math . 110 ] & \\ f = \frac{106.2}{360} \times 200 = 59 ( Hz ) & ( 110 )\end{matrix}$$

In FIG. 24, the real-time frequency follows a theoretical frequency with a delay of about one cycle ( 1/60=16.67 ms) after 0.05 second. Sufficient accuracy in a practically acceptable level is considered to be obtained.

The case 2 is explained. Parameters of the case 2 are as shown in Table 10 below.

TABLE 10
Parameters of the case 2

| Item name | Setting value | |
|---|---|---|
| Power system rated frequency | 60 | Hz |
| Data collection sampling | 4000 | Hz |
| frequency f₁ | | |
| Gauge sampling frequency f_{S} | 80 | Hz |
| Real-time frequency f | 59.25 | Hz |
| Alternating-current voltage | 1 | V |
| amplitude V | | |
| Alternating-current voltage | 0 | Deg |
| initial phase angle | | |
| Frequency fluctuation | Suddenly increase 5 Hz from | |
| occurrence time t₁ | point in time of 0.05 S | |
| Moving average length T_{avg} | 8.33 | ms |
| Simulation end time T_{end} | 0.4 | S |

Note that the case 2 is equivalent to G.4 Frequency step test (+5 Hz) in P 49 to 50 of IEEE C27. 118-2005, IEEE Standard for Synchrophasors for Power System. Note that the standard is setting for causing a frequency change of +5 hertz from the nominal frequency (60 hertz). However, the case 2 is set to cause a frequency change of +5 hertz from an abnormal frequency (59.25 hertz). That is, the setting (the case 2) of this application is stricter than the standard.

The simulation is explained again. First, a voltage instantaneous value waveform is represented as indicated by the following formula on the basis of Table 10.

$$\begin{matrix} [ Math . 111 ] & \\ v = \{ \begin{matrix}cos ( 2 π f t ) = cos ( 370.71 t ) & for t < 0.05 , \\ cos [ 2 π ( f + df ) t + {φ}_{c} ] = cos ( 402.12 t + {φ}_{c} ) & for t \geq 0.05 .\end{matrix} & ( 111 )\end{matrix}$$

In the above formula, φ_{c} represents a voltage phase angle at a change point in time (t=0.05 s). According to the above table, a ratio (n) of the data collection sampling frequency and the gauge sampling frequency in this simulation is as indicated by the following formula:

$$\begin{matrix}[ Math . 112 ] & \\ n = \frac{4000}{80} = 50 & ( 112 )\end{matrix}$$

In this simulation, the number of data points of the moving average processing is as indicated by the following formula:

$$\begin{matrix}[ Math . 113 ] & \\ M = int ( \frac{{T}_{avg}}{{T}_{1}} ) = int ( \frac{0.00833}{1 / 4000} ) = 33 & ( 113 )\end{matrix}$$

This numerical value is about a half cycle of the system nominal frequency. Note that, because a gauge sampling frequency of 80 hertz is lower than a double of the power system nominal frequency, a rotation phase angle is a negative number.

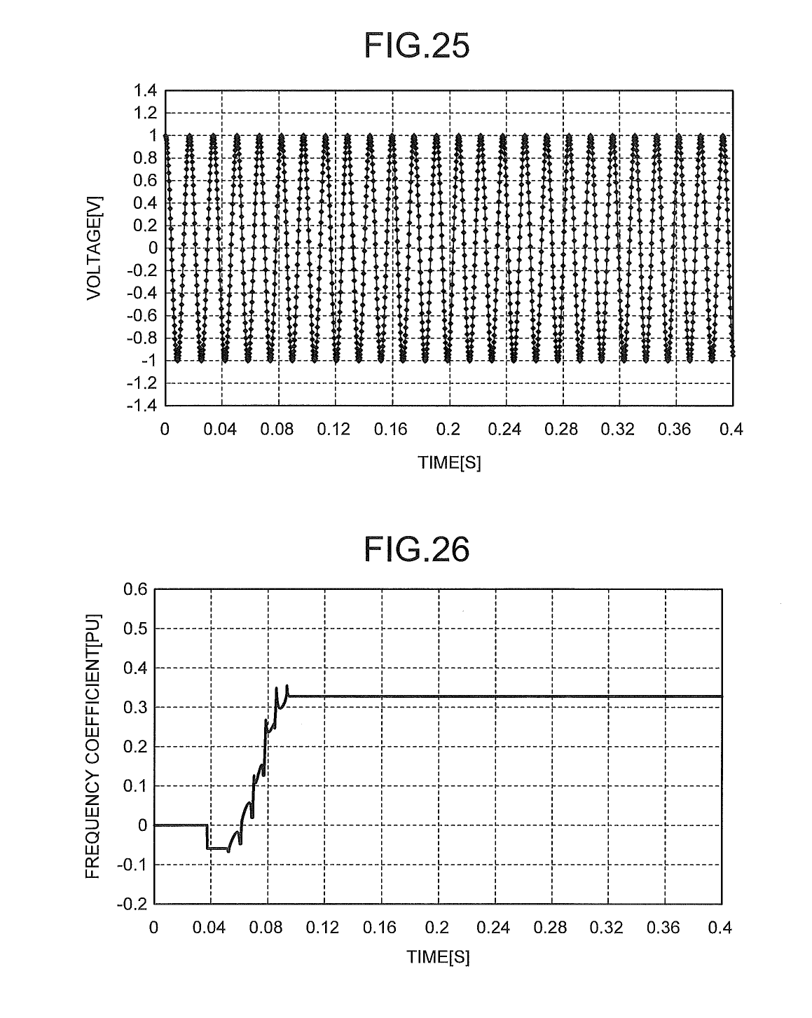

FIG. 25 is a diagram of a voltage instantaneous value waveform in the case 2. It is seen that, in the case 2, as in the case 1, a data sampling frequency is set to 4000 hertz and a large number of data are collected.

FIG. 26 is a diagram of a measurement result of a frequency coefficient in the case 2. A frequency coefficient before a frequency changes can be calculated as indicated by the following formula:

$$\begin{matrix}[ Math . 114 ] & \\ {f}_{c} = \frac{{v}_{21} + {v}_{23}}{2 {v}_{22}} = - 0.07846 ( PU ) & ( 114 )\end{matrix}$$

Note that, in the case 1 and the case 2, although the real-time frequencies are substantially the same (the case 1: 59 hertz, the case 2: 59.25 hertz), because the gauge sampling frequencies are different (the case 1: 200 hertz, the case 2: 80 hertz), vales of the frequency coefficients are also different.

The frequency coefficient after the change of the frequency can be calculated as indicated by the following formula:

$$\begin{matrix}[ Math . 115 ] & \\ {f}_{c} = \frac{{v}_{21} + {v}_{23}}{2 {v}_{22}} = 0.3090 ( PU ) & ( 115 )\end{matrix}$$

As it is evident from Formula (114) and Formula (115), the frequency coefficient changes from a negative value to a positive value.

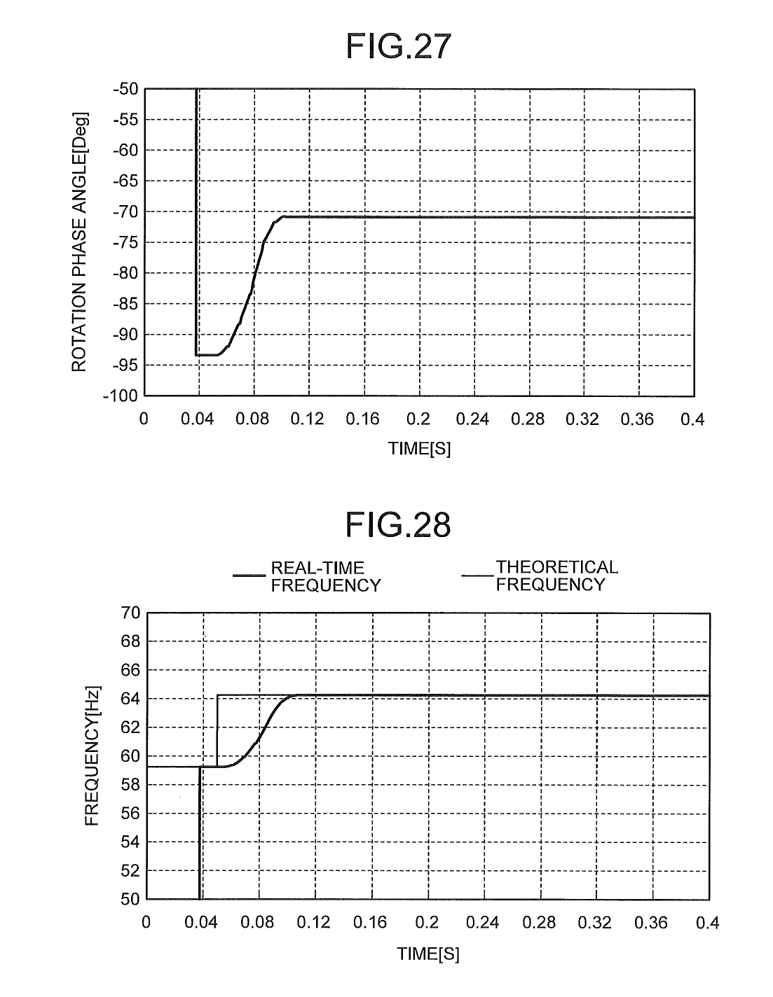

FIG. 27 is a diagram of a measurement result of a rotation phase angle in the case 2. The rotation phase angle before the frequency changes can be calculated as indicated by the following formula:

[Math. 116]

α=cos⁻¹f_{c}=cos⁻¹(−0.07846)=−94.5(Deg) (116)

The rotation phase angle after the change of the frequency can be calculated as indicated by the following formula:

[Math. 117]

α=cos⁻¹f_{c}=cos⁻¹(0.3090)=−72(Deg) (117)

Note that, in the case 2, because the real-time frequency is equal to or higher than a half (40 hertz) of the gauge sampling frequency, the rotation phase angle is a negative value before and after the change (see Formulas (116) and (117)).

FIG. 28 is a diagram of a measurement result of the real-time frequency in the case 2. The real-time frequency before the frequency changes can be calculated as indicated by the following formula:

$$\begin{matrix}[ Math . 118 ] & \\ f = ( 1 - \frac{94.5}{360} ) \times 80 = 59 ( Hz ) & ( 118 )\end{matrix}$$

According to FIG. 28, the real-time frequency follows a sudden increase in a theoretical frequency with a delay of about two to three cycles after 0.05 second. Sufficient accuracy in a practically acceptable level is considered to be obtained.

The real-time frequency after the change of the frequency can be calculated as indicated by the following formula:

$$\begin{matrix}[ Math . 119 ] & \\ f = ( 1 - \frac{72}{360} ) \times 80 = 64 ( Hz ) & ( 119 )\end{matrix}$$

Parameters of the case 3 are as shown in Table 11 below. Note that, in the case 3, a real-time frequency, an alternating-current voltage amplitude, and an alternating-current voltage initial phase angle are unknown.

TABLE 11
Parameters of the case 3

| Item name | Setting value | |
|---|---|---|
| Power system rated frequency | 60 | Hz |
| Data collection sampling | 4000 | Hz |
| frequency f₁ | | |
| Gauge sampling frequency f_{S} | 80 | Hz |
| Real-time frequency f | Unknown | |
| Alternating-current voltage | Unknown | |
| amplitude V | | |
| Alternating-current voltage | Unknown | |
| initial phase angle | | |
| Moving average length T_{avg} | 33.33 | ms |
| Simulation end time T_{end} | 1.2 | S |

According to the above table, a ratio (n) of the data collection sampling frequency and the gauge sampling frequency in this simulation is as indicated by the following formula:

$$\begin{matrix}[ Math . 120 ] & \\ n = \frac{4000}{200} = 20 & ( 120 )\end{matrix}$$

In this simulation, the number of data points of the moving average processing is as indicated by the following formula:

$$\begin{matrix}[ Math . 121 ] & \\ M = int ( \frac{{T}_{avg}}{{T}_{1}} ) = int ( \frac{0.03333}{1 / 4000} ) = 133 & ( 121 )\end{matrix}$$

This numerical value is about two cycles of the system nominal frequency.

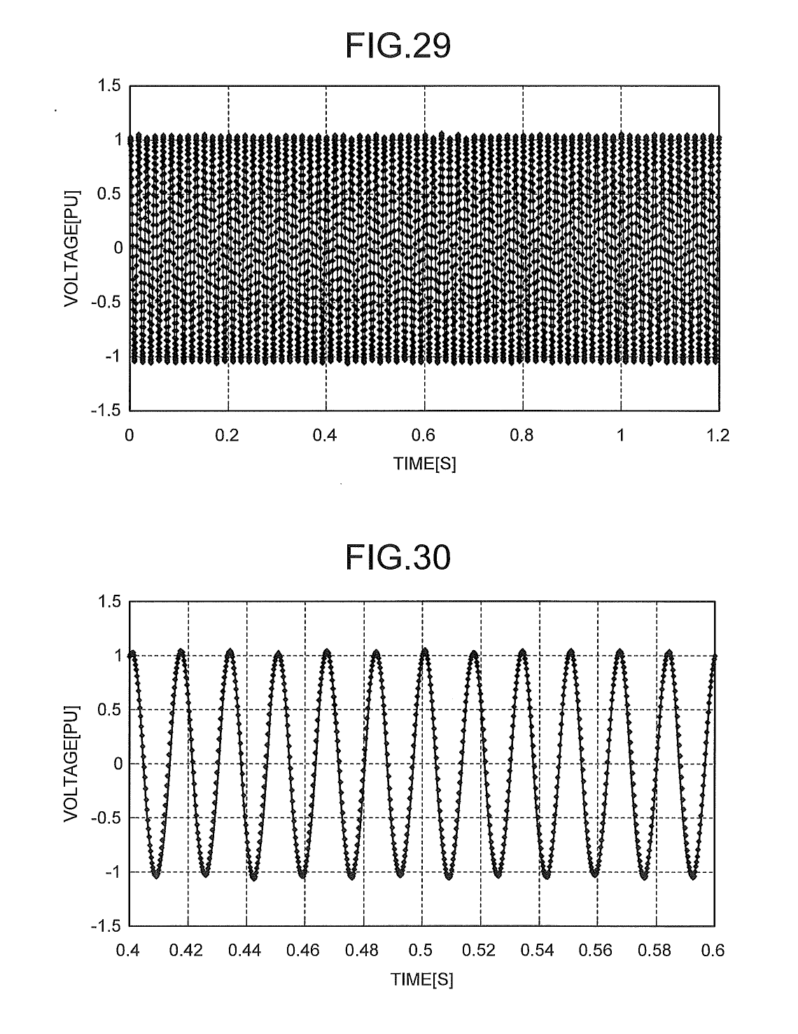

FIG. 29 is a diagram showing a first voltage instantaneous value waveform in the case 3. It is seen that, in the case 3, a data sampling frequency is set to 4000 hertz and a large number of data are collected. FIG. 29 shows voltage instantaneous value data up to 1.2 seconds. Note that, in this case, a unit of a voltage instantaneous value is PU and is a value on a secondary side of a transformer substation CT. When necessary, an actual voltage value can be calculated according to a CT ratio.

FIG. 30 is a diagram showing a second voltage instantaneous value waveform in the case 3. A range is expanded to show data in 0.4 to 0.6 second. In the cases 1 and 2, the heights of peak values of the voltage instantaneous value waveform are aligned in the entire time domain. On the other hand, it is seen that, in the case 3, the heights of peak values of the voltage instantaneous value waveform subtly vary. This is considered to be an influence due to on and off of a power system load.

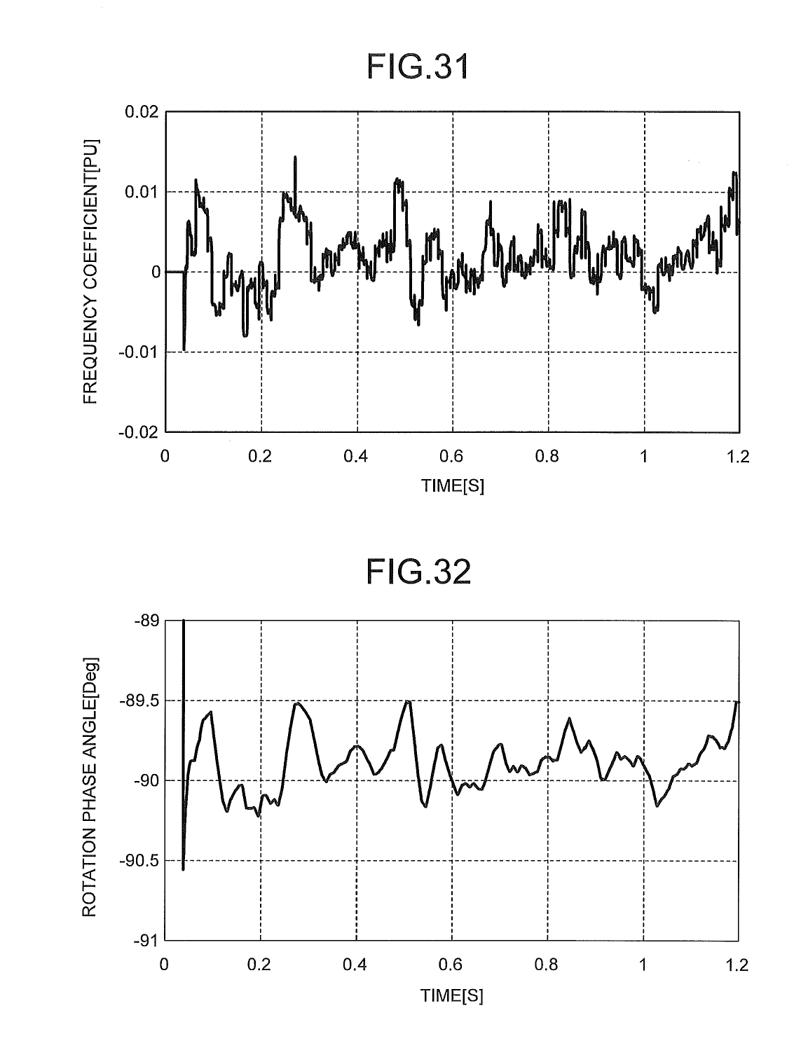

FIG. 31 is a diagram of a measurement result of a frequency coefficient in the case 3. It is seen that, in the case 3, the frequency coefficient intensely fluctuates because a large number of voltage flickers (phase oscillations) are included in setting data of a simulation.

FIG. 32 is a diagram of a measurement result of a rotation phase angle in the case 3. It is seen that, in the case 3, the rotation phase angle also intensely fluctuates because the large number of voltage flickers (phase oscillations) are included in the setting data of the simulation.

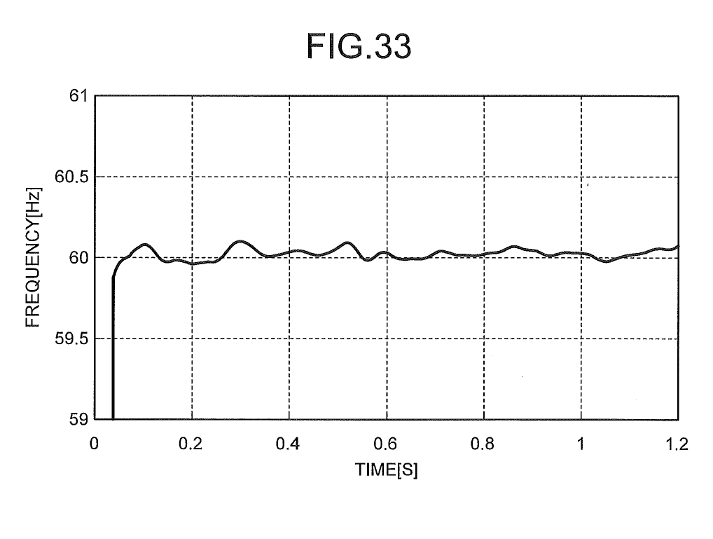

FIG. 33 is a diagram of a measurement result of a real-time frequency in the case 3. In the case 3, the real-time frequency also oscillates because the large number of voltage flickers (phase oscillations) are included in the setting data of the simulation. However, fluctuation width of the measurement result of the real-time frequency is 59.9 to 60.1 hertz and is relatively small. Therefore, if the measuring apparatus according to the first embodiment is applied to a frequency relay or a frequency change rate relay, it is possible to use the measuring apparatus as a real-time-frequency measuring apparatus having both of high speed and high accuracy.

Note that, in the first embodiment, as an example, the method of this application is applied to the frequency measuring apparatus. However, the application of the method is not limited to this. It is also possible to apply the method of this application to an apparatus that measures an alternating-current current amplitude and a direct current.

### Second Embodiment

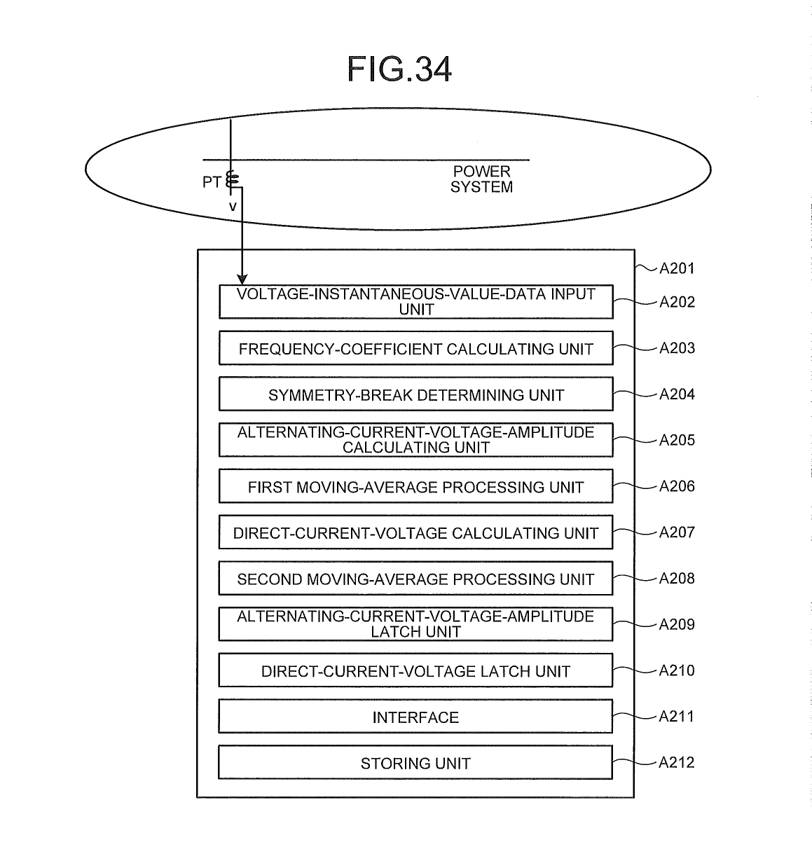

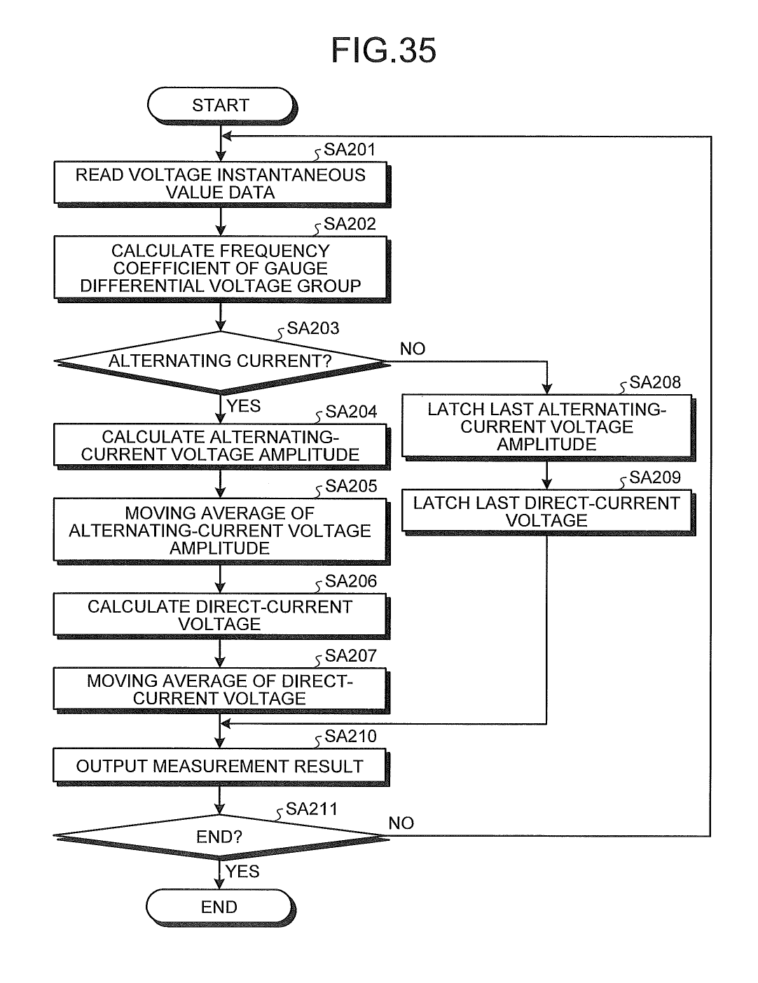

FIG. 34 is a diagram of a functional configuration of a voltage measuring apparatus according to a second embodiment. FIG. 35 is a flowchart for explaining a flow of processing in the voltage measuring apparatus.

As shown in FIG. 34, a voltage measuring apparatus A201 according to the second embodiment includes a voltage-instantaneous-value-data input unit A202, a frequency-coefficient calculating unit A203, a symmetry-break determining unit A204, an alternating-current-voltage-amplitude calculating unit A205, a first moving-average processing unit A206, a direct-current voltage calculating unit A207, a second moving-average processing unit A208, an alternating-current-voltage-amplitude latch unit A209, a direct-current-voltage latch unit A210, an interface A211, and a storing unit A212. The interface A211 performs processing for outputting a calculation result and the like to a display device and an external device. The storing unit A212 performs processing for storing measurement data, a calculation result, and the like.

(Step SA201)

In the configuration explained above, the voltage-instantaneous-value-data input unit A202 performs processing for reading out a voltage instantaneous value from a potential transformer (PT) provided in a power system. Note that data of the read-out voltage instantaneous value is stored in the storing unit A212.

(Step SA202)

The frequency-coefficient calculating unit A203 calculates a frequency coefficient using the reproduced following formula as in the first embodiment:

$$\begin{matrix}[ Math . 122 ] & \\ {f}_{c} = \frac{{v}_{21} + {v}_{23}}{2 {v}_{22}} & ( 122 )\end{matrix}$$

(Step SA203)

The symmetry-break determining unit A204 determines a break of symmetry using the reproduced following formula as in the first embodiment:

$$\begin{matrix}[ Math . 123 ] & \\ \vert {f}_{c} \vert = \vert \frac{{v}_{21} + {v}_{23}}{2 {v}_{22}} \vert > 1 & ( 123 )\end{matrix}$$

When Formula (123) does not hold, the symmetry-break determining unit A204 determines that symmetry is not broken (i.e., a waveform is a pure alternating-current waveform) (Yes at step SA203) and shifts to step SA204.

(Step SA204)

For calculation of an alternating-current voltage amplitude, a gauge differential voltage group is used. The alternating-current-voltage-amplitude calculating unit A205 calculates the alternating-current voltage amplitude using the following formula and the formula following the following formula:

$$\begin{matrix}[ Math . 124 ] & \\ {v}_{gd} = \sqrt{{v}_{22}^{2} - {v}_{21} {v}_{23}} & ( 124 ) \\ [ Math . 125 ] & \\ v = \frac{{v}_{gd}}{\sqrt{2 ( 1 + {f}_{c} ) ( 1 - {f}_{c} )}} & ( 125 )\end{matrix}$$

In Formulas (124) and (125), v₂₁, v₂₂, and v₂₃ represent differential voltage instantaneous values, v_{gd} represents a gauge differential voltage, f_{c} represent frequency coefficient, and V represents an alternating-current voltage amplitude.

(Step SA205)

The first moving-average processing unit A206 performs moving average processing for the alternating-current voltage amplitude using the following formula:

$$\begin{matrix}[ Math . 126 ] & \\ v = \frac{1}{m} {\sum }_{k = 0}^{M - 1} v ( t - {kT}_{1} ) & ( 126 )\end{matrix}$$

(Step SA206)

The direct-current-voltage calculating unit A207 calculates a direct-current voltage using the following formula:

$$\begin{matrix}[ Math . 127 ] & \\ {v}_{DC} = \frac{{v}_{11} + {v}_{13} - 2 {v}_{12} {f}_{c}}{2 ( 1 - {f}_{c} )} & ( 127 )\end{matrix}$$

(Step SA207)

The second moving-average processing unit A208 performs moving average processing for the direct-current voltage using the following formula and shifts to step SA210:

$$\begin{matrix}[ Math . 128 ] & \\ {v}_{DC} = \frac{1}{M} {\sum }_{k = 0}^{M - 1} {v}_{DC} ( t - {kT}_{1} ) & ( 128 )\end{matrix}$$

(Step SA208)

On the other hand, when Formula (123) holds, the symmetry-break determining unit A204 determines that symmetry is broken (i.e., a waveform is not a pure alternating-current waveform) (No at step SA203). The alternating-current-voltage-amplitude latch unit A209 latches the last measurement value related to the alternating-current voltage amplitude using the following formula (step SA208):

[Math. 129]

V(t)=V(t−T₁) (129)

In the above formula, V(t−T₁) represents the last measurement value related to the alternating-current amplitude.

Following step SA208, the direct-current-voltage latch unit A210 latches the last measurement value related to the direct-current voltage using the following formula (step SA209).

[Math. 130]

v_{DC}(t)=v_{DC}(t−T₁) (130)

In the above formula, V_{Dc}(t−T₁) represents the last measurement value related to the alternating-current voltage amplitude.

(Step SA210)

The voltage measuring apparatus A201 outputs a measurement result. Note that the measurement result is used as a frequency relay and voltage amplitude information of a power system state monitoring point.

(Step SA211)

The voltage measuring apparatus A201 determines whether the processing ends. If the processing does not end (No at step SA211), the voltage measuring apparatus A201 returns to step SA201. On the other hand, if the processing ends (Yes at step SA211), the voltage measuring apparatus A201 leaves the flow.

Utility and effects of the voltage measuring apparatus according to the second embodiment are explained on the basis of a simulation result obtained using numerical value examples of cases 4 and 5.

Parameters of the case 4 are as shown in Table 12 below.

TABLE 12
Parameters of the case 4

| Item name | Setting value | |
|---|---|---|
| Power system rated frequency | 60 | Hz |
| Data collection sampling | 4000 | Hz |
| frequency f₁ | | |
| Gauge sampling frequency f_{S} | 200 | Hz |
| Real-time frequency f | 59 | Hz |
| Alternating-current voltage | 1 | V |
| amplitude V | | |
| Alternating-current voltage | 30 | Deg |
| initial phase angle | | |
| Direct-current voltage V_{DC} | 2 | V |
| Alternating-current voltage | Decrease 40% at | |
| amplitude sudden change | time of 0.05 S | |
| occurrence time t1 | | |
| Moving average length T_{avg} | 16.67 | ms |
| Simulation end time T_{end} | 0.4 | S |

Note that the case 4 is equivalent to G.2 Magnitude step test (10%) in P 47 to 48 of IEEE C27. 118-2005, IEEE Standard for Synchrophasors for Power System. Note that, in the standard, a nominal frequency is set to 60 hertz, a direct current component is set to zero, and change width of an alternating-current voltage is set to 10%. However, in the case 4, a direct-current component is larger than an alternating-current voltage amplitude, change width of an alternating-current voltage is 40%, and an initial value of a frequency at which the alternating-current voltage amplitude changes starts from 59 hertz, which is not the nominal frequency. Therefore, setting of the case 4 is stricter than the standard.

The simulation is explained again. First, a voltage instantaneous value waveform is represented as indicated by the following formula on the basis of Table 12.

$$\begin{matrix} [ Math . 131 ] & \\ v = \{ \begin{matrix}{v}_{DC} + cos ( 2 π ft + {φ}_{0} ) = 2 + cos ( 370.71 t + 0.5236 ) & for t < 0.5 , \\ {v}_{DC} + 0.6 cos ( 2 π ft + {φ}_{C} ) = 2 + 0.6 cos ( 370.71 t + {φ}_{C} ) & for t \geq 0.05 .\end{matrix} & ( 131 )\end{matrix}$$

In the above formula, φ₀ represents an initial phase angle and φ_{c} represents a voltage phase angle at a change point in time (t=0.05 s).

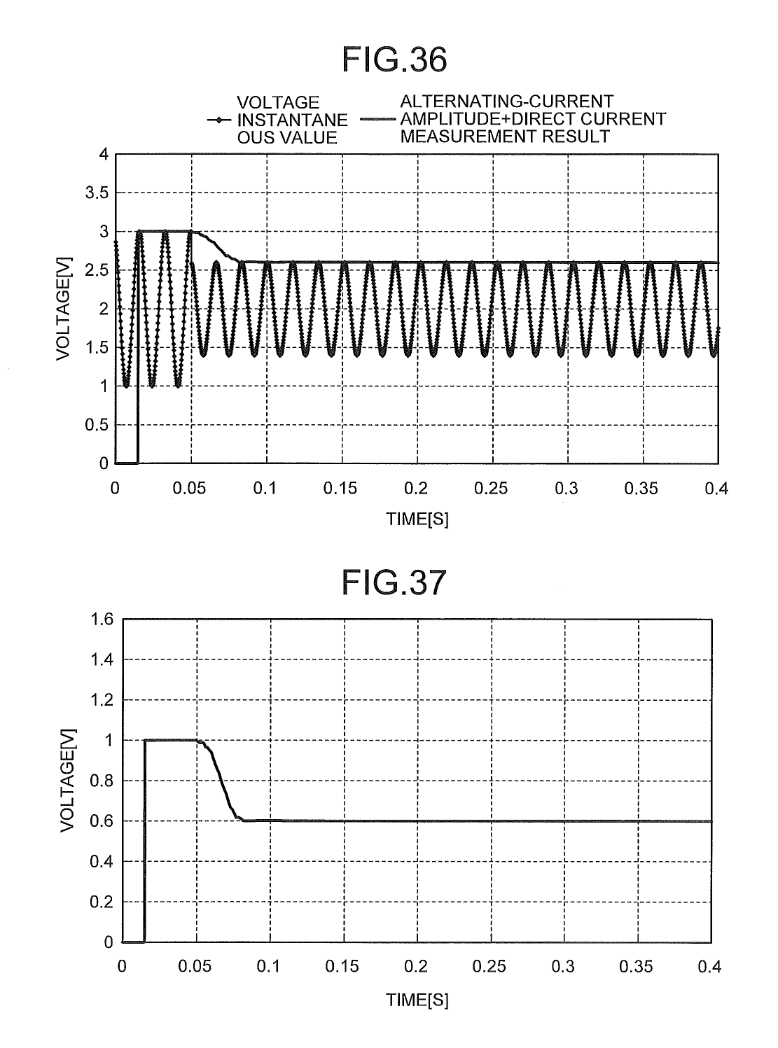

FIG. 36 is a diagram of a voltage instantaneous value waveform and a measurement result of an alternating-current voltage amplitude superimposed with a direct-current voltage in the case 4. It is seen that, in the case 4 as well, a data sampling frequency is set to 4000 hertz and a large number of data are collected. It is seen that the measurement result of the alternating-current voltage amplitude superimposed with the direct-current voltage follows an actual waveform at high speed.

FIG. 37 is a diagram of a measurement result of an alternating-current voltage amplitude in the case 4. The alternating-current voltage amplitude before fluctuation occurs can be calculated as indicated by the following formula:

$$\begin{matrix}[ Math . 132 ] & \\ V = \frac{1}{1 - {f}_{C}} \sqrt{\frac{{v}_{22}^{2} - {v}_{21} {v}_{23}}{2 ( 1 + {f}_{C} )}} = 1.0 ( V ) & ( 132 )\end{matrix}$$

The alternating-current voltage amplitude after the fluctuation occurs can be calculated as indicated by the following formula:

$$\begin{matrix}[ Math . 133 ] & \\ V = \frac{1}{1 - {f}_{C}} \sqrt{\frac{{v}_{22}^{2} - {v}_{21} {v}_{23}}{2 ( 1 + {f}_{C} )}} = 0.6 ( V ) & ( 133 )\end{matrix}$$

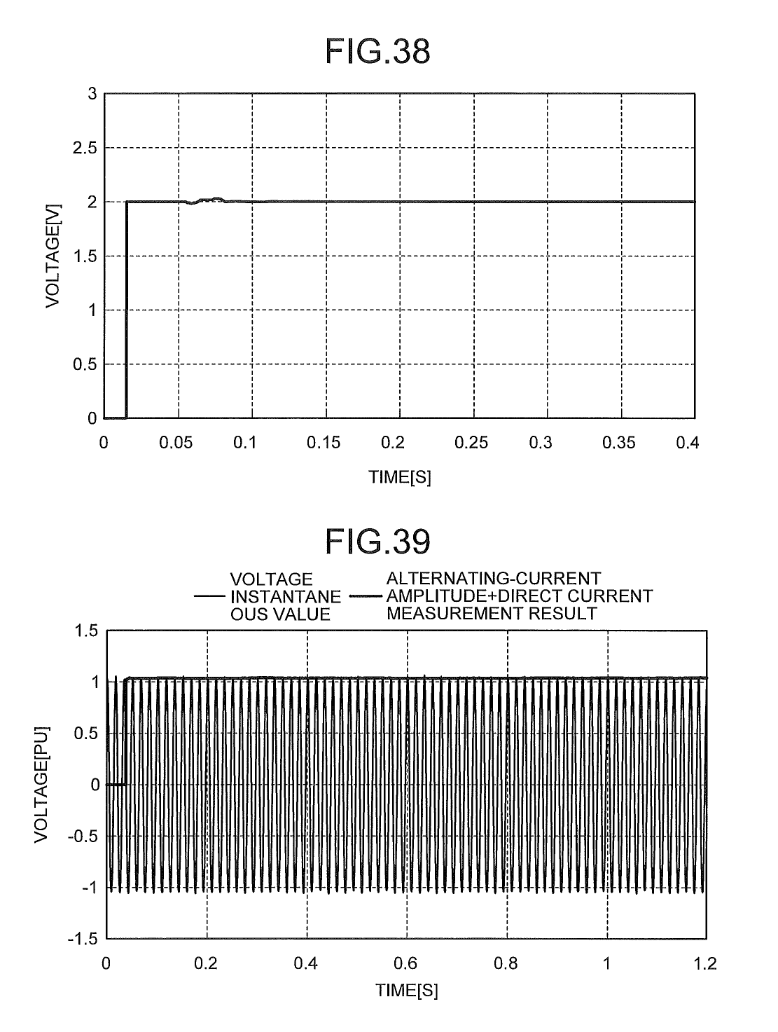

FIG. 38 is a diagram of a measurement result of a direct-current voltage in the case 4. The direct-current voltage can be calculated as indicated by the following formula:

$$\begin{matrix}[ Math . 134 ] & \\ {v}_{DC} = \frac{{v}_{11} + {v}_{13} - 2 {v}_{12} {f}_{c}}{2 ( 1 - {f}_{c} )} = 2.0 ( V ) & ( 134 )\end{matrix}$$

Parameters of the case 5 are as shown in Table 13 below. Note that, in the case 5, a real-time frequency, an alternating-current voltage amplitude, and an alternating-current voltage initial phase angle, and a direct-current voltage are unknown.

TABLE 13
Parameters of the case 5

| Item name | Setting value | |
|---|---|---|
| Power system rated frequency | 60 | Hz |
| Data collection sampling | 4000 | Hz |
| frequency f₁ | | |
| Gauge sampling frequency f_{S} | 80 | Hz |
| Real-time frequency f | Unknown | |
| Alternating-current voltage | Unknown | |
| amplitude V | | |
| Alternating-current voltage | Unknown | |
| initial phase angle | | |
| Direct-current voltage V_{DC} | Unknown | |
| Moving average length T_{avg} | 33.33 | ms |
| Simulation end time T_{end} | 1.2 | S |

FIG. 39 is a diagram of a voltage instantaneous value waveform and a measurement result of an alternating-current voltage amplitude superimposed with a direct-current voltage in a case 5. As shown in FIG. 39 as a thick line, it is seen that the measurement result of the alternating-current voltage amplitude superimposed with the direct-current voltage follows an actual waveform at high speed.

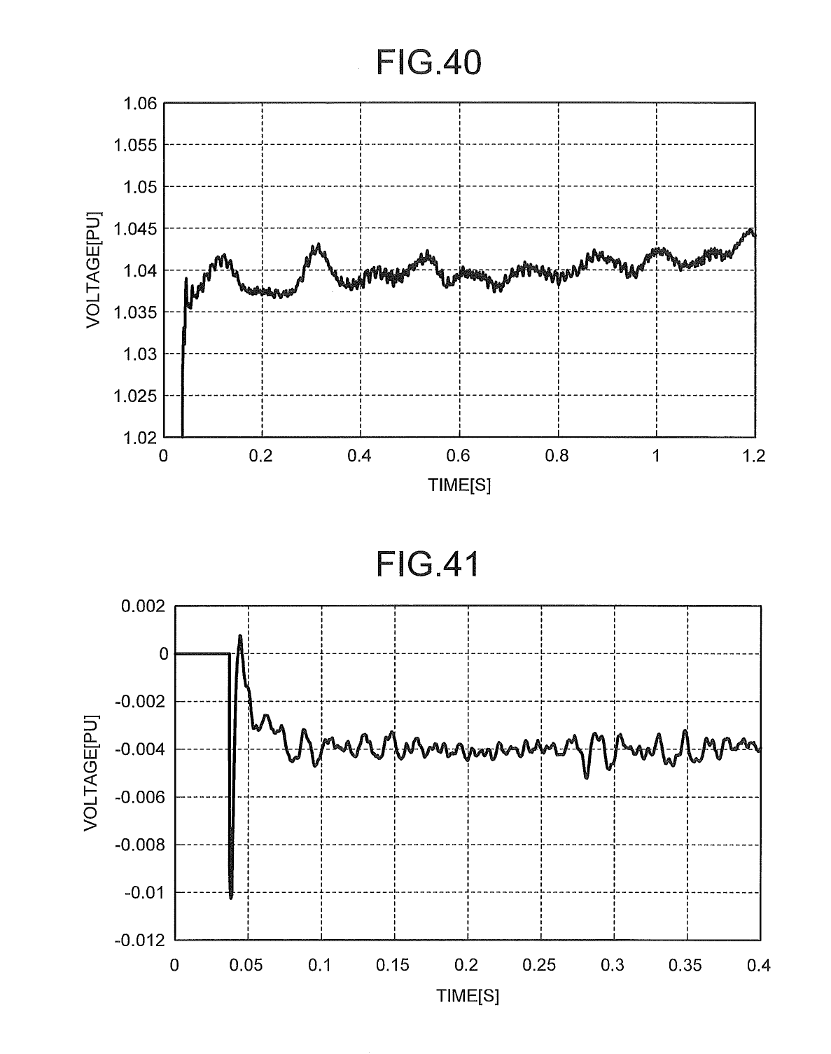

FIG. 40 is a diagram of a measurement result of an alternating-current voltage amplitude in the case 5. It is seen that, in the case 5 as well, although a fine fluctuation component occurs in the measurement result of the alternating-current voltage amplitude because a large number of voltage flickers (phase oscillations) are included in setting data of a simulation, fluctuation width is 1.035 to 1.045 (PU) and is suppressed within 1% of the alternating-current voltage amplitude.

FIG. 41 is a diagram of a measurement result of a direct-current voltage in the case 5. In the measurement result shown in FIG. 41 as well, it is seen that a fine fluctuation component occurs, however, a direct-current offset component is about −0.004 (PU). Note that the measurement result can be used for setting of AI correction (analog input amount correction) of a digital protection control apparatus.

Note that, in the second embodiment, as an example, the method of this application is applied to the apparatus that measures the alternating-current voltage amplitude and the direct-current voltage. However, the application of the method is not limited to this. It is also possible to apply the method of this application to an apparatus that measures an alternating current amplitude and a direct current.

The configurations explained in the first and second embodiments above are examples of the configuration of the present invention. The configurations can be combined with other publicly-known technologies and can be changed by, for example, omitting a part of the configurations in a range not departing from the spirit of the present invention.

### INDUSTRIAL APPLICABILITY

As explained above, the present invention is useful as an electric-quantity measuring apparatus that enables highly accurate measurement of an electric quantity even when a measurement target is operating at a frequency deviating from a system nominal frequency.

### REFERENCE SIGNS LIST

A101 Real-time-frequency measuring apparatus
A102, A202 Voltage-instantaneous-value-data input units
A103, A203 Frequency-coefficient calculating units
A104, A204 Symmetry-break determining units
A105 Frequency-coefficient latch unit
A106 First moving-average processing unit (frequency coefficient)
A107 Rotation-phase-angle calculating unit
A108 Second moving-average processing unit (rotation phase angle)
A109 Frequency calculating unit
A110 Third moving-average processing unit (real-time frequency)
A111 Communication unit
A112, A211 Interfaces
A113, A212 Storing units
A201 Voltage measuring apparatus
A205 Alternating-current-voltage-amplitude calculating unit
A206 First moving-average processing unit (alternating-current voltage amplitude)
A207 Direct-current voltage calculating unit
A208 Second moving-average processing unit (direct-current voltage)
A209 Alternating-current-voltage-amplitude latch unit
A210 Direct-current-voltage latch unit

1. An electric-quantity measuring apparatus comprising:
a rotation-phase-angle calculating unit that calculates, as a rotation phase angle between adjacent voltage instantaneous value data, an arc cosine value of a value obtained by normalizing, with a differential voltage instantaneous value at intermediate time, an average of a sum of differential voltage instantaneous values at time other than the intermediate time among differential voltage instantaneous value data at three points representing an inter-distal end distance between voltage instantaneous value data at adjacent two points in voltage instantaneous value data at continuous at least four points extracted, out of voltage instantaneous value data obtained by sampling a measurement target alternating-current voltage at a predetermined first sampling frequency, at a second sampling frequency lower than the first sampling frequency and equal to or higher than a frequency of the alternating-current voltage; and
a frequency calculating unit that calculates a frequency of the alternating-current voltage using the second sampling frequency and the rotation phase angle.

2. The electric-quantity measuring apparatus according to claim 1, wherein
the rotation phase angle takes a positive value when the frequency of the alternating-current voltage is lower than a half of the second sampling frequency, and
the rotation phase angle takes a negative value when the frequency of the alternating-current voltage is higher than a half of the second sampling frequency and lower than the second sampling frequency.

3. The electric-quantity measuring apparatus according to claim 2, wherein the electric-quantity measuring apparatus calculates the frequency of the alternating-current voltage as a half of the second sampling frequency when the rotation phase angle takes a zero value.

4. The electric-quantity measuring apparatus according to claim 1, further comprising an alternating-current-voltage-amplitude calculating unit that calculates, as a gauge differential voltage, a value obtained by averaging a difference between a square value of the differential voltage instantaneous value at the intermediate time and a product of the differential voltage instantaneous value data at the time other than the intermediate time among differential voltage instantaneous value data at three points representing an inter-distal end distance between voltage instantaneous value data at adjacent two points in voltage instantaneous value data at continuous at least four points including the differential voltage instantaneous value data at the three points used in calculating the rotation phase angle and calculates amplitude of the alternating-current voltage using the rotation phase angle and the gauge differential voltage.

5. The electric-quantity measuring apparatus according to claim 4, further comprising a direct-current-voltage calculating unit that calculates a direct-current voltage, which is superimposed on the alternating-current voltage, on the basis of the rotation phase angle and voltage instantaneous value data at continuous three points among the voltage instantaneous value data at the four points used in calculating the rotation phase angle.

6. The electric-quantity measuring apparatus according to claim 1, further comprising an alternating-current-voltage-amplitude calculating unit that calculates amplitude of the alternating-current voltage on the basis of the rotation phase angle and voltage instantaneous value data at continuous two points among the voltage instantaneous value data at the four points used in calculating the rotation phase angle.

7. The electric-quantity measuring apparatus according to claim 1, further comprising an alternating-current-voltage-amplitude calculating unit that calculates amplitude of the alternating-current voltage on the basis of the rotation phase angle and differential voltage instantaneous value data at continuous three points among the voltage instantaneous value data at the four points used in calculating the rotation phase angle.

8. The electric-quantity measuring apparatus according to claim 4, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.

9. An electric-quantity measuring apparatus comprising:
a frequency-coefficient calculating unit that calculates, as a frequency coefficient, a value obtained by normalizing, with a differential voltage instantaneous value at intermediate time, an average of a sum of differential voltage instantaneous values at time other than the intermediate time among differential voltage instantaneous value data at three points representing an inter-distal end distance between voltage instantaneous value data at adjacent two points in voltage instantaneous value data at continuous at least four points extracted, out of voltage instantaneous value data obtained by sampling a measurement target alternating-current voltage at a predetermined first sampling frequency, at a second sampling frequency lower than the first sampling frequency and equal to or higher than a frequency of the alternating-current voltage; and
a frequency calculating unit that calculates a frequency of the alternating-current voltage using the second sampling frequency and the frequency coefficient.

10. The electric-quantity measuring apparatus according to claim 9, further comprising an alternating-current-voltage-amplitude calculating unit that calculates, as a gauge differential voltage, a value obtained by averaging a difference between a square value of the differential voltage instantaneous value at the intermediate time and a product of the differential voltage instantaneous value data at the time other than the intermediate time among differential voltage instantaneous value data at three points representing an inter-distal end distance between voltage instantaneous value data at adjacent two points in voltage instantaneous value data at continuous at least four points including the differential voltage instantaneous value data at the three points used in calculating the frequency coefficient and calculates amplitude of the alternating-current voltage using the frequency coefficient and the gauge differential voltage.

11. The electric-quantity measuring apparatus according to claim 10, further comprising a direct-current-voltage calculating unit that calculates a direct-current voltage, which is superimposed on the alternating-current voltage, on the basis of the frequency coefficient and voltage instantaneous value data at continuous three points among the voltage instantaneous value data at the four points used in calculating the frequency coefficient.

12. The electric-quantity measuring apparatus according to claim 9, further comprising an alternating-current-voltage-amplitude calculating unit that calculates amplitude of the alternating-current voltage on the basis of the frequency coefficient and voltage instantaneous value data at continuous two points among the voltage instantaneous value data at the four points used in calculating the frequency coefficient.

13. The electric-quantity measuring apparatus according to claim 9, further comprising an alternating-current-voltage-amplitude calculating unit that calculates amplitude of the alternating-current voltage on the basis of the frequency coefficient and differential voltage instantaneous value data at continuous three points among the voltage instantaneous value data at the four points used in calculating the frequency coefficient.

14. The electric-quantity measuring apparatus according to claim 10, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.

15. (canceled)

16. (canceled)

17. The electric-quantity measuring apparatus according to claim 6, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.

18. The electric-quantity measuring apparatus according to claim 7, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.

19. The electric-quantity measuring apparatus according to claim 12, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.

20. The electric-quantity measuring apparatus according to claim 13, further comprising a symmetry-break determining unit that determines a break of symmetry of a waveform of the alternating-current voltage using a determination index based on a deviation between a first voltage amplitude calculated using a first calculation formula capable of calculating the amplitude of the alternating-current voltage and a second voltage amplitude calculated using a second calculation formula different from the first calculation formula.
